(19) United States
(12) Patent Application Publication
(10) Pub. No.: US 2023/0060585 A1
(43) Pub. Date: Mar. 2, 2023

(54) RESIST UNDERLYING FILM-FORMING COMPOSITION FOR NANOIMPRINTING

(71) Applicant: NISSAN CHEMICAL CORPORATION, Tokyo (JP)

(72) Inventors: Hikaru TOKUNAGA, Toyama-shi (JP); Makoto NAKAJIMA, Toyama-shi (JP)

(73) Assignee: NISSAN CHEMICAL CORPORATION, Tokyo (JP)

(21) Appl. No.: 17/783,453

(22) PCT Filed: Dec. 10, 2020
(86) PCT No.: PCT/JP2020/046020

§ 371 Date: Jun. 8, 2022

(30) Foreign Application Priority Data
Dec. 18, 2019 (JP) 2019-228038

(51) Int. Cl. G03F 7/11; C08G 12/26; C09D 161/26; C08G 12/08; C09D 161/22; C08G 4/00; C09D 161/00; G03F 7/00; G03F 7/16; H01L 21/027; H01L 21/311; H01L 21/308

(52) U.S. Cl. CPC G03F 7/11; C08G 12/26; C09D 161/26; C08G 12/08; C09D 161/22; C08G 4/00; C09D 161/00; G03F 7/0002; G03F 7/168; H01L 21/0274; H01L 21/31144; H01L 21/3086

(57) ABSTRACT

A composition for forming resist underlayer film for nanoimprinting includes novolac resin that has a repeating unit structure represented by formula (1). In formula (1), group A represents organic group having an aromatic ring, a condensed aromatic ring, or a condensed aromatic heterocycle, group B represents organic group having an aromatic ring or a condensed aromatic ring, group E represents a single bond or a branched or straight-chain C1-10 alkylene group that may be substituted and may include an ether bond and/or a carbonyl group, group D represents organic group that has 1 to 15 carbon atoms and is represented by formula (2) (in which R¹, R², and R³ each independently represent a fluorine atom, or a straight-chain, branched-chain, or cyclic alkyl group, and any two of R¹, R², and R³ may be bonded to one another to form a ring), and n represents a number from 1 to 5.

### TECHNICAL FIELD

The present invention relates to a resist underlying film-forming composition for nanoimprinting, a resist underlying film which is a cured product of an applied film comprising the composition, a method for producing the resist underlying film, and a method for forming a pattern and a method for producing a semiconductor device, each method using the resist underlying film.

### BACKGROUND ART

In the production of a semiconductor device, an MEMS, and others, which are required to be further scaled down, a photo-nanoimprinting technique of enabling formation of a microstructure on the order of several nanometers on a substrate has attracted attention. This is a technique, in which a curable composition (resist) is applied onto a substrate (wafer), a mold (die) having a fine uneven pattern formed on the surface thereof is pressed against the resist, the resist in this state is cured by heat or a light so that the uneven pattern of the mold is transferred to the resist cured film, and the mold is separated, forming a pattern on the substrate.

In a general photo-nanoimprinting technique, a resist composition in a liquid state is first dropwise applied onto a region of a substrate, in which a pattern is to be formed, using, for example, an inkjet method so that droplets of the resist composition spread over the substrate (prespread). Then, the resist composition is patterned using a mold (die), which is transparent with respect to the irradiation light and has a formed pattern. In this instance, the droplets of the resist composition spread over the entire area of the gap between the substrate and the mold due to capillary phenomena (spread). The resist composition also fills the inside of the depressed portions of the mold due to capillary phenomena (fill). A period of time required until the “spread” and “fill” are completed is a filling time. After completion of filling with the resist composition, the resist composition is cured by irradiation with a light, and then the cured resist composition and the mold are separated. By conducting these steps, a resist pattern having a predetermined form is formed on the substrate.

In the release step for the photo-nanoimprinting technique, adhesion between the resist composition and the substrate is important. This is because, when the adhesion between the resist composition and the substrate is low, it is likely that a pattern peel defect is caused, that is, upon separating the mold in the release step, part of the photo-cured product obtained by curing the resist composition is peeled and remains on the mold as a deposit. As a technique for improving the adhesion between the resist composition and the substrate, a technique, in which an adhesion layer is formed between the resist composition and the substrate as a layer for closely bonding the resist composition and the substrate, has been proposed.

Further, in the nanoimprinting pattern formation, a high etching-resistance layer may be used. As a material for the high etching-resistance layer, organic materials or silicone materials are generally used. Further, on the resist underlying film for nanoimprinting, an adhesion layer or a silicone layer containing Si may be formed by application or vapor deposition. In the case where the adhesion layer or silicone layer containing Si is hydrophobic and exhibits a high pure-water contact angle, an increased adhesion between the layer and a resist underlying film is expected, so that the layer and the film are unlikely to be released from each other, when the resist underlying film is also hydrophobic and exhibits a high pure-water contact angle.

It has been known that, for example, He, H₂, N₂, and air are relatively hydrophobic at room temperature, and therefore these gases have high affinity with a film having a high contact angle, and the permeability of the film to the gas is expected to be increased. For this reason, as a material for the resist underlying film, a material having a high water contact angle is preferred.

### CITATION LIST

### Patent Literature

Patent Literature 1: JP 2019-36725 A

### SUMMARY OF INVENTION

### Technical Problem

Accordingly, an object of the present invention is to provide a resist underlying film-forming composition for nanoimprinting, which is advantageous not only in that the composition exhibits excellent planarization property, provides a highly hydrophobic film after being baked, and gives the film an improved adhesion with the hydrophobic upper layer film, but also in that it permits controlling the optical constants and etching rate so as to be suitable for the process by changing the molecular skeleton of the resin.

### Solution to Problem

The present invention encompasses the followings.

[1] A resist underlying film-forming composition for nanoimprinting, comprising a novolac resin having a repeating unit structure represented by the following formula (1):

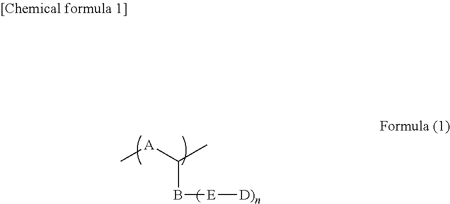

wherein:
group A represents an organic group having an aromatic ring, a fused aromatic ring, or a fused aromatic heterocycle;
group B represents an organic group having an aromatic ring or a fused aromatic ring;
group E represents a single bond, or a branched or linear alkylene group having 1 to 10 carbon atoms, which is optionally substituted and optionally contains an ether linkage and/or a carbonyl group;
group D represents an organic group having 1 to 15 carbon atoms, which is represented by the following formula (2);

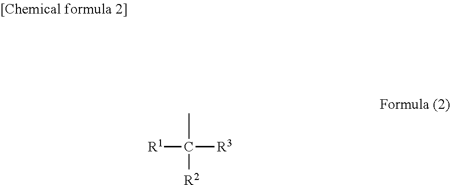

wherein each of R¹, R², and R³ is independently a fluorine atom or a linear, branched, or cyclic alkyl group, and any two of R¹, R², and R³ are optionally bonded to each other to form a ring; and
n represents a number of 1 to 5.

[2] The resist underlying film-forming composition for nanoimprinting according to item [1] above, wherein the group D is a tert-butyl group or a trifluoromethyl group.

[3] The resist underlying film-forming composition for nanoimprinting according to item [1] or [2] above, wherein the organic group having an aromatic ring, a fused aromatic ring, or a fused aromatic heterocycle for the group A is an organic group having one or more than one benzene rings, naphthalene rings, anthracene rings, or pyrene rings, or a fused ring between a benzene ring and a heterocycle or aliphatic ring.

[4] The resist underlying film-forming composition for nanoimprinting according to any one of items [1] to [3] above, wherein the organic group having an aromatic ring, a fused aromatic ring, or a fused aromatic heterocycle for the group A is an organic group having 6 to 30 carbon atoms and optionally containing at least one heteroatom selected from N, S, and O on the ring, in the ring, or between the rings.

[5] The resist underlying film-forming composition for nanoimprinting according to any one of items [1] to [4] above, wherein the group A is at least one member selected from the following groups:

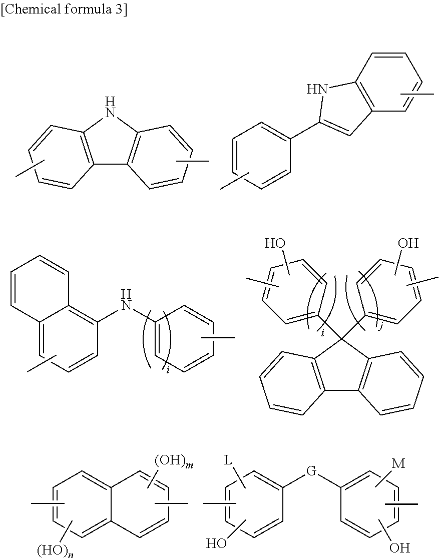

wherein each of i, j, m, and n is independently 1 or 2, G represents a direct bond or any one of the following formulae:

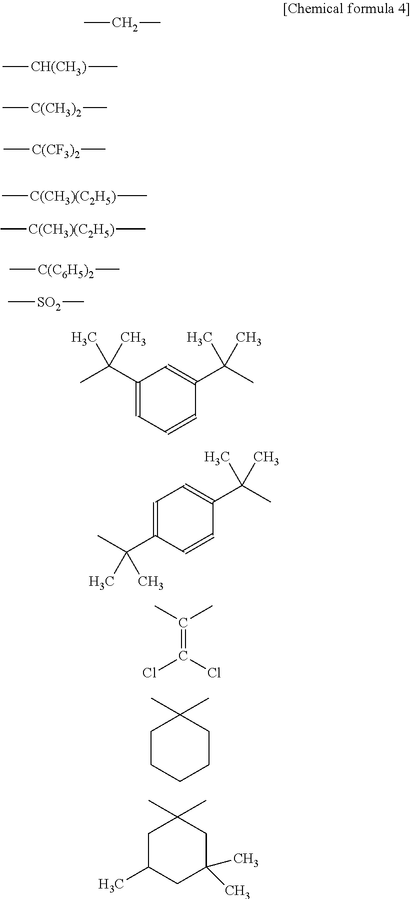

and
each of L and M independently represents a hydrogen atom, a phenyl group, or a C₁₋₃ alkyl group.

[6] The resist underlying film-forming composition for nanoimprinting according to any one of items [1] to [5] above, wherein the group B is phenylene, biphenylene, naphthalenediyl, anthracenediyl, or phenanthrenediyl.

[7] The resist underlying film-forming composition for nanoimprinting according to any one of items [1] to [6] above, wherein the group E is a single bond or a linear alkylene group having 1 to 6 carbon atoms.

[8] The resist underlying film-forming composition for nanoimprinting according to any one of items [1] to [7] above, wherein the group E is a single bond.

[9] The resist underlying film-forming composition for nanoimprinting according to any one of items [1] to [8] above, wherein the composition which has been baked at 240° C. gives a pure-water contact angle of 76° or more, and the composition which has been baked at 350° C. gives a pure-water contact angle of 70° or more.

[10] The resist underlying film-forming composition for nanoimprinting according to any one of items [1] to [9] above, further comprising a crosslinking agent.

[11] The resist underlying film-forming composition for nanoimprinting according to any one of items [1] to [10] above, further comprising at least one member selected from the group consisting of an acid, a salt thereof, and an acid generator.

[12] The resist underlying film-forming composition for nanoimprinting according to item [10] or [11] above, wherein the composition which has been baked at 350° C. gives a pure-water contact angle of 65° or more.

[13] A resist underlying film which is a cured product of an applied film comprising the resist underlying film-forming composition for nanoimprinting according to any one of items [1] to [12] above.

[14] A method for producing a resist underlying film, comprising applying the resist underlying film-forming composition for nanoimprinting according to any one of items [1] to [12] above onto a semiconductor substrate and baking the applied composition.

[15] A method for forming a pattern, comprising the steps of:

forming on a semiconductor substrate a resist underlying film from the resist underlying film-forming composition for nanoimprinting according to any one of items [1] to [12] above;

applying a curable composition onto the resist underlying film;

allowing the curable composition and a mold to be in contact;

irradiating the curable composition with a light or an electron beam to form a cured film; and

separating the cured film and the mold.

[16] The method for forming a pattern according to item [15] above, wherein the step of applying a curable composition onto the resist underlying film comprises forming an adhesion layer and/or a silicone layer containing Si in an amount of 99% by mass or less or 50% by mass or less by application or vapor deposition on the resist underlying film, and applying the curable composition onto the formed layer.

[17] A method for producing a semiconductor device, comprising the steps of: forming on a semiconductor substrate a resist underlying film from the resist underlying film-forming composition for nanoimprinting according to any one of items [1] to [12] above;

forming a resist film on the resist underlying film;

irradiating the resist film with a light or an electron beam and subjecting the resultant resist film to development to form a resist pattern;

etching the resist underlying film through the formed resist pattern; and

processing the semiconductor substrate using the patterned resist underlying film.

[18] A method for producing a semiconductor device, comprising the steps of:

forming on a semiconductor substrate a resist underlying film from the resist underlying film-forming composition for nanoimprinting according to any one of items [1] to [12] above;

forming a hard mask on the resist underlying film;

forming a resist film on the hard mask;

irradiating the resist film with a light or an electron beam and subjecting the resultant resist film to development to form a resist pattern;

etching the hard mask through the formed resist pattern;

etching the resist underlying film through the patterned hard mask; and

processing the semiconductor substrate using the patterned resist underlying film.

### Advantageous Effects of Invention

The novolac resin according to the present invention exhibits especially high pure-water contact angle (=hydrophobic) not only when baked at low temperatures but also when baked at high temperatures. Moreover, the novolac resin according to the present invention, when made into a material by mixing the novolac resin with a crosslinking agent, an acid catalyst, and a surfactant also exhibits a specifically high pure-water contact angle (=hydrophobic), when baked at high temperatures. By virtue of this, it is possible to impart the resultant film an improved adhesion with the hydrophobic upper layer film, and it is expected that the film has an excellent permeability to hydrophobic gas. Furthermore, the novolac resin in the present invention exhibits an excellent planarization property and permits controlling the optical constants and etching rate so as to be suitable for the process by changing the molecular skeleton of the novolac resin.

### DESCRIPTION OF EMBODIMENTS

[Resist Underlying Film-Forming Composition for Nanoimprinting]

The resist underlying film-forming composition for nanoimprinting of the present invention comprises a novolac resin having a repeating unit structure represented by the following formula (1):

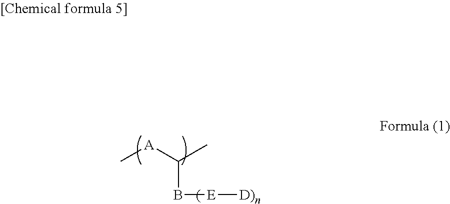

wherein:
group A represents an organic group having an aromatic ring, a fused aromatic ring, or a fused aromatic heterocycle;
group B represents an organic group having an aromatic ring or a fused aromatic ring;
group E represents a single bond, or a branched or linear alkylene group having 1 to 10 carbon atoms, which is optionally substituted and optionally contains an ether linkage and/or a carbonyl group;
group D represents an organic group having 1 to 15 carbon atoms, which is represented by the following formula (2):

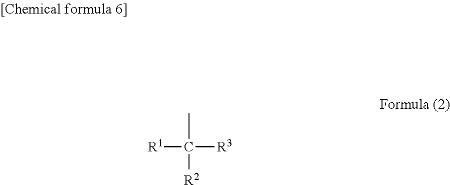

wherein each of R¹, R², and R³ is independently a fluorine atom or a linear, branched, or cyclic alkyl group, and any two of Rr, R², and R³ are optionally bonded to each other to form a ring; and
n represents a number of 1 to 5,
   and optionally contains a solvent and other components. The components of the composition are successively described below.

[Novolac Resin Having a Repeating Unit Structure Represented by Formula (1)]

The “organic group having an aromatic ring” for group A and group B is a group having a hydrocarbon, which is a monocycle and aromatic. Examples include benzene, cyclooctatetraene, and groups derived from toluene, xylene, mesitylene, cumene, or styrene, each optionally having one or more substituents. Further examples include an organic group having a fused ring of an aromatic ring, such as benzene, and an aliphatic ring, such as cyclohexane, cyclohexene, methylcyclohexane, or methylcyclohexene; and an organic group having a fused ring of an aromatic ring, such as benzene, and a heterocycle, such as furan, thiophene, pyrrole, imidazole, pyran, pyridine, pyrimidine, pyrazine, pyrrolidine, piperidine, piperazine, and morpholine.

The “organic group having a fused aromatic ring” for group A and group B is a group having a hydrocarbon, which is a fused ring and aromatic. Examples include groups derived from indene, naphthalene, azulene, anthracene, phenanthrene, naphthacene, triphenylene, pyrene, or chrysene.

The “organic group having a fused aromatic heterocycle” for group A is a group having a hydrocarbon, which is a fused ring and aromatic and contains one or more heteroatoms. Examples include groups derived from indole, purine, quinoline, isoquinoline, chromene, thianthrene, phenothiazine, phenoxazine, xanthene, acridine, phenazine, or carbazole.

The above-mentioned aromatic ring, fused aromatic ring, and fused aromatic heterocycle may be linked to each other, for example, through an alkylene group.

The organic group having an aromatic ring, a fused aromatic ring, or a fused aromatic heterocycle for group A is preferably an organic group having 6 to 30 carbon atoms.

The organic group having an aromatic ring, a fused aromatic ring, or a fused aromatic heterocycle for group A is preferably an organic group having one or more than one benzene rings or naphthalene rings, or a fused ring between a benzene ring and a heterocycle or aliphatic ring.

The organic group having an aromatic ring, a fused aromatic ring, or a fused aromatic heterocycle for group A is preferably an organic group having 6 to 30 carbon atoms and optionally containing at least one heteroatom selected from N, S, and O on the ring, in the ring, or between the rings. Examples of heteroatoms contained on the ring include a nitrogen atom contained in an amino group (e.g., a propargylamino group) or a cyano group, an oxygen atom contained in a formyl group, a hydroxy group, a carboxyl group, or an alkoxy group (e.g., a propargyloxy group), and a nitrogen atom and an oxygen atom contained in a nitro group. Examples of heteroatoms contained in the ring include an oxygen atom contained in xanthene and a nitrogen atom contained in carbazole. Examples of heteroatoms contained between the rings include a nitrogen atom, an oxygen atom, and a sulfur atom contained in an —NH— bond, an —NHCO— bond, an —O— bond, a —COO— bond, a —CO— bond, an —S— bond, an —SS— bond, or an —SO₂— bond.

Group A is preferably at least one member selected from the following groups:

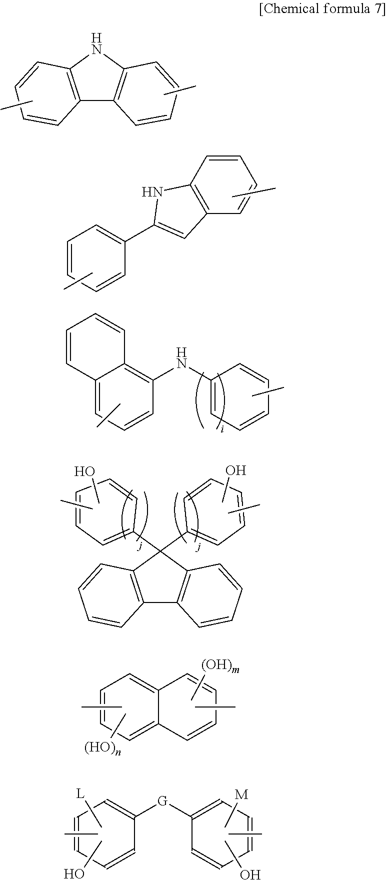

wherein each of i, j, m, and n is independently 1 or 2; G represents a direct bond or any one of the following formulae:

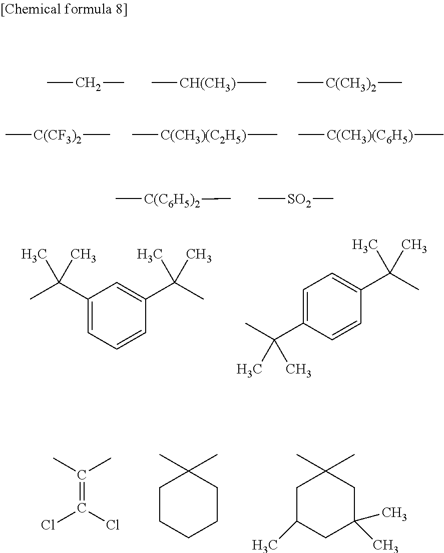

and
each of L and M independently represents a hydrogen atom, a phenyl group, or a C₁₋₃ alkyl group.

Group A is preferably at least one member selected from the following groups.

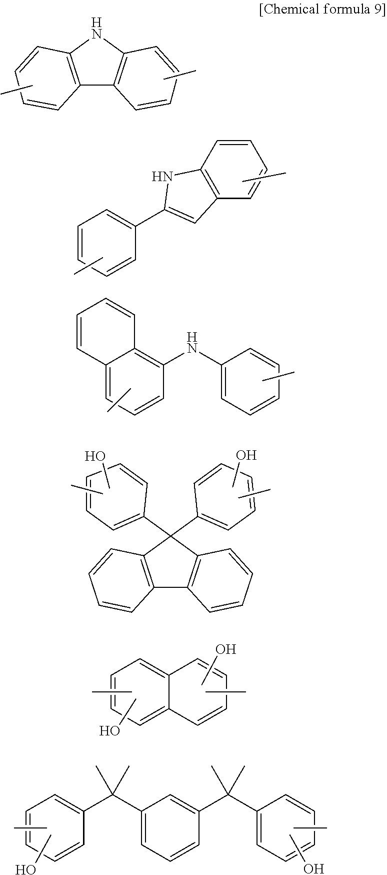

Group B is preferably phenylene, biphenylene, naphthalenediyl, anthracenediyl, or phenanthrenediyl.

Group D represents an organic group having 1 to 15 carbon atoms and being represented by formula (2) above, preferably an organic group having 1 to 12 carbon atoms, having 1 to 10 carbon atoms, having 1 to 8 carbon atoms, having 1 to 6 carbon atoms, having 1 to 5 carbon atoms, or having 1 to 4 carbon atoms.

Examples of the “linear, branched, or cyclic alkyl group” for R, R², and R³ include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group. Further, any two of R¹, R², and R³ may be bonded to each other to form a ring.

Group D is preferably a tert-butyl group or a trifluoromethyl group.

Group E is a single bond or a linear alkylene group having 1 to 6 carbon atoms. Examples of linear alkylene groups include a methylene group, an ethylene group, a propylene group, a butylene group, a pentylene group, and a hexylene group. Group E is preferably a single bond.

n is a number of 1 to 5, 1 to 4, or 1 to 3, preferably 1, 2, 3, 4, or 5, more preferably 1, 2, 3, or 4, most preferably 1, 2, or 3.

[Synthesis Method]

The novolac resin having a repeating unit structure represented by formula (1) may be prepared by a known method. For example, the novolac resin may be prepared by subjecting a ring-containing compound represented by H-A-H and an aldehyde compound represented by OHC-B-E-D to condensation (wherein A, B, E, and D are as defined above). With respect to each of the ring-containing compound and the aldehyde compound, a single species may be used, or two or more species may be used in combination. In this condensation reaction, the aldehyde compound may be used in an amount of 0.1 to 10 moles, preferably 0.1 to 2 moles, per mole of the ring-containing compound.

As the catalyst used in the condensation reaction, a mineral acid, such as sulfuric acid, phosphoric acid, or perchloric acid; an organic sulfonic acid, such as p-toluenesulfonic acid, p-toluenesulfonic acid monohydrate, or methanesulfonic acid; or a carboxylic acid, such as formic acid or oxalic acid, may be used. The amount of the catalyst used varies depending on the type of the catalyst used, but is generally within the range of 0.001 to 10,000 parts by mass, preferably 0.01 to 1,000 parts by mass, more preferably 0.05 to 100 parts by mass, relative to 100 parts by mass of the ring-containing compound (or the total of the ring-containing compounds).

The condensation reaction may be conducted without using a solvent, but is generally conducted using a solvent. With respect to the solvent, there is no particular limitation as long as it can dissolve therein the reaction substrate and does not inhibit the reaction. Examples of solvents include 1,2-dimethoxyethane, diethylene glycol dimethyl ether, propylene glycol monomethyl ether, propylene glycol monomethyl ether acetate, tetrahydrofuran, and dioxane. The condensation reaction temperature is generally within the range of 40 to 200° C., preferably 100 to 180° C. The reaction time varies depending on the reaction temperature, but is generally within the range of 5 minutes to 50 hours, preferably 5 minutes to 24 hours.

The novolac resin having a repeating unit structure represented by formula (1) generally has a weight average molecular weight of 500 to 100,000, preferably 600 to 80,000, 800 to 60,000, or 1,000 to 50,000.

When the novolac resin having a repeating unit structure represented by formula (1) in the present invention is dissolved in a solvent without adding an additive, such as a crosslinking agent, and applied onto a substrate (silicon wafer), it gives a pure-water contact angle of 76° or more, when baked at 240° C., and a pure-water contact angle of 70° or more, when baked at 350° C.

[Solvent]

The resist underlying film-forming composition for nanoimprinting of the present invention may contain a solvent. With respect to the solvent, there is no particular limitation as long as it can dissolve therein the novolac resin having a repeating unit structure represented by formula (1) and an optional component added if necessary. Particularly, the resist underlying film-forming composition for nanoimprinting of the present invention is used in a uniform solution state, and therefore, taking the application properties of the composition into consideration, it is recommended that a solvent generally used in a lithography process should be also used.

Examples of such solvents include methyl cellosolve acetate, ethyl cellosolve acetate, propylene glycol, propylene glycol monomethyl ether, propylene glycol monoethyl ether, propylene glycol monopropyl ether, methylisobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N, N-dimethylformamide, N-methylacetamide, N,N-dimethylacetamide, N-methylpyrrolidone, 4-methyl-2-pentanol, and γ-butyrolactone. These solvents may be used each alone or in combination of two or more.

Of these, more preferred are propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate; and further preferred are propylene glycol monomethyl ether and propylene glycol monomethyl ether acetate.

[Crosslinking Agent]

The resist underlying film-forming composition for nanoimprinting of the present invention may contain a crosslinking agent. Examples of the crosslinking agents include melamines, substituted ureas, and polymers thereof. Preferred are crosslinking agents having at least two crosslink-forming substituents, and examples include compounds, such as methoxymethylated glycoluril (for example, tetramethoxymethylglycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, and methoxymethylated thiourea. Further, condensation products of the above compound may be used.

With respect to the crosslinking agent, a crosslinking agent having a high heat resistance may be used. With respect to the crosslinking agent having a high heat resistance, a compound containing in the molecule thereof a crosslink-forming substituent having an aromatic ring (for example, a benzene ring or a naphthalene ring) may be preferably used.

Examples of the compounds include compounds having a partial structure of formula (4) below, and polymers or oligomers having repeating units of formula (5) below.

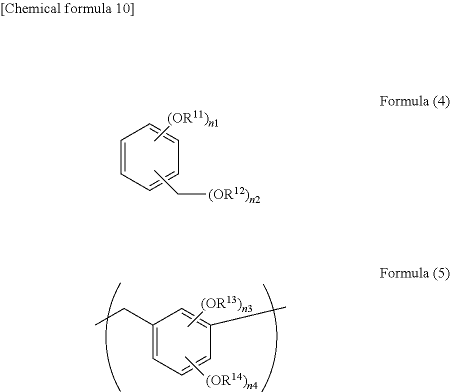

The above-mentioned R¹¹, R¹², R¹³, and R¹⁴ are a hydrogen atom or an alkyl group having 1 to 10 carbon atoms, and, as the alkyl group, those mentioned above as examples of alkyl groups may be used. n1 represents an integer of 1 to 4, n2 represents an integer of 1 to (5−n1), and (n1+n2) represents an integer of 2 to 5. n3 represents an integer of 1 to 4, n4 represents 0 to (4−n3), and (n3+n4) represents an integer of 1 to 4. An oligomer or polymer, in which the number of repeating unit structures is in the range of from 2 to 100 or from 2 to 50, may be used.

Examples of the compounds, polymers, and oligomers of formulae (4) and (5) are shown below.

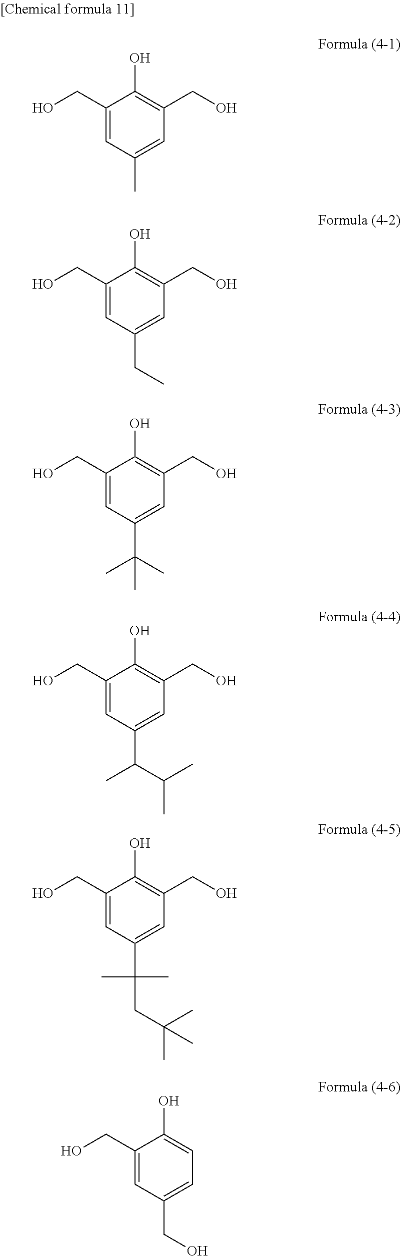

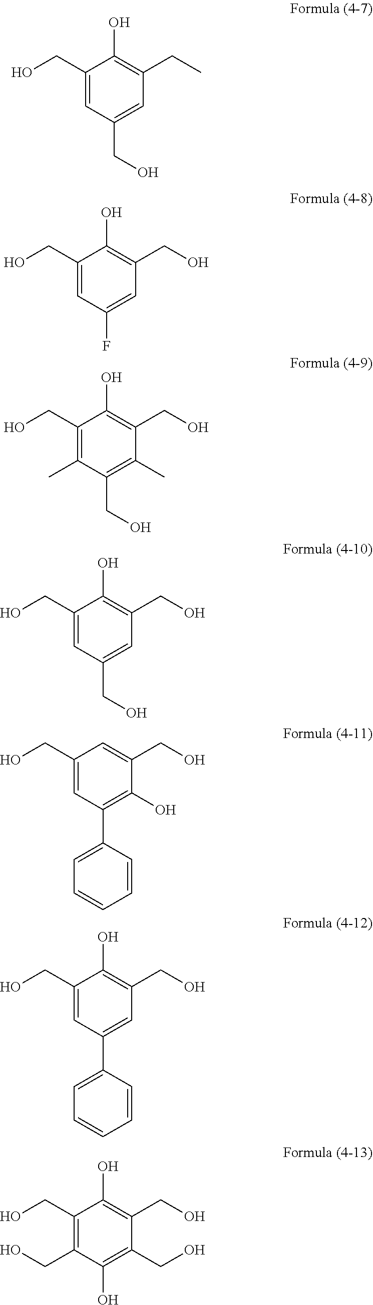

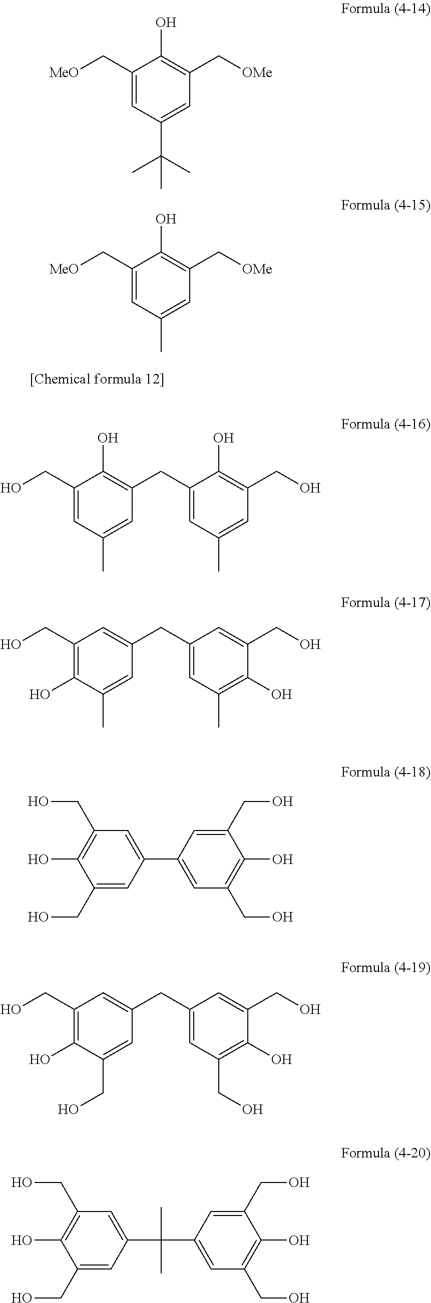

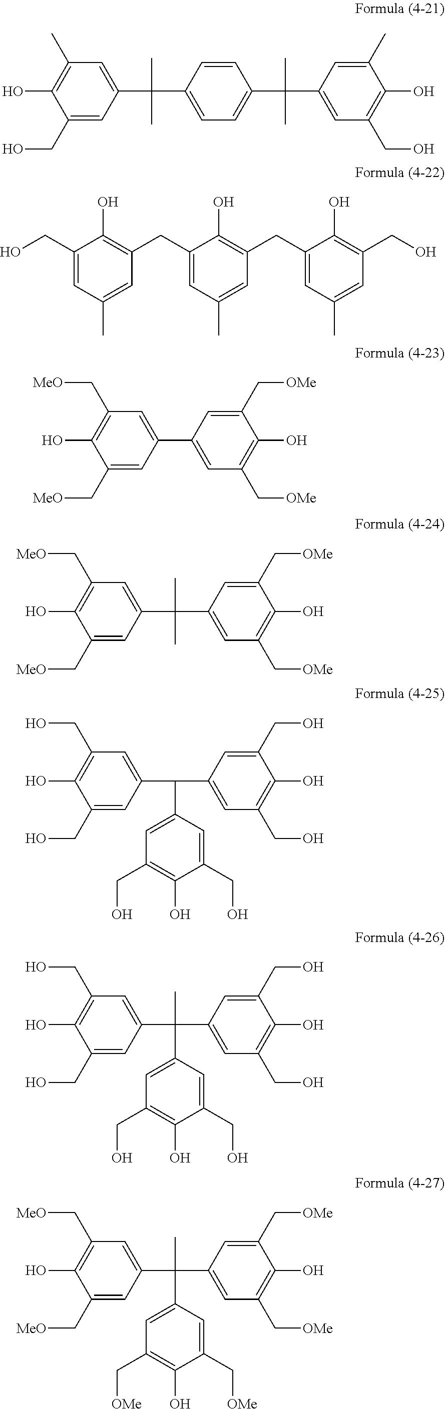

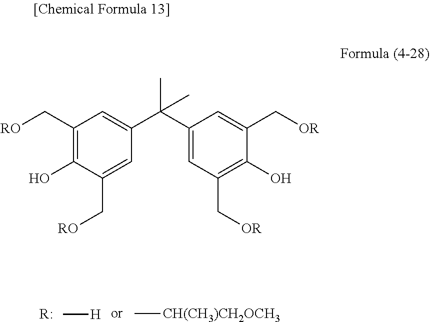

The above-mentioned compounds are available as products of Asahi Yukizai Corporation and Honshu Chemical Industry Co., Ltd. For example, among the above-mentioned crosslinking agents, the compound of formula (4-23) is available as trade name: TMOM-BP, manufactured by Honshu Chemical Industry Co., Ltd., the compound of formula (4-24) is available as trade name: TM-BIP-A, manufactured by Asahi Yukizai Corporation, and the compound of formula (4-28) is available as trade name: PGME-BIP-A.

The amount of the crosslinking agent added varies depending on, for example, the application solvent used, the substrate used, the required solution viscosity, or the required film form, but it is 0.001% by mass or more, 0.01% by mass or more, 0.05% by mass or more, 0.5% by mass or more, or 1.0% by mass or more, and 80% by mass or less, 50% by mass or less, 40% by mass or less, 20% by mass or less, or 10% by mass or less, based on the total solid content of the resist underlying film-forming composition. The crosslinking agent possibly causes a crosslinking reaction due to self-condensation, but, when a crosslinkable substituent is present in the above-mentioned polymer in the present invention, the crosslinking agent and the crosslinkable substituent may together cause a crosslinking reaction.

[Acid and/or Salt Thereof and/or Acid Generator]

The resist underlying film-forming composition for nanoimprinting of the present invention may contain an acid and/or a salt thereof and/or an acid generator.

Examples of acids include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

With respect to the salt, a salt of the above-mentioned acid may be used. The salt is not limited, but, for example, salts derived from ammonia, such as a trimethylamine salt or a triethylamine salt; salts derived from pyridine; or salts derived from morpholine may be preferably used.

With respect to the acid and/or salt thereof, a single species may be used, or two or more species may be used in combination. The amount of the acid or salt incorporated is generally within the range of 0.0001 to 20% by mass, preferably 0.0005 to 10% by mass, further preferably 0.01 to 5% by mass, based on the total solid content of the resist underlying film-forming composition.

Examples of acid generators include a thermal acid generator and a photo-acid generator.

Examples of thermal acid generators include 2,4,4,6-tetrabromocyclohexadienone, benzoin tosylate, 2-nitrobenzyl tosylate, K-PURE [registered trademark] CXC-1612, K-PURE CXC-1614, K-PURE TAG-2172, K-PURE TAG-2179, K-PURE TAG-2678, K-PURE TAG2689, K-PURE TAG2700 (manufactured by King Industries, Inc.), SI-45, SI-60, SI-80, SI-100, SI-110, SI-150 (manufactured by Sanshin Chemical Industry Co., Ltd.), and other organic sulfonic acid alkyl esters.

The photo-acid generator generates an acid upon exposure for the resist. Therefore, the acidity of the resist underlying film can be controlled. This is one measure for conforming the acidity of the resist underlying film to the acidity of the resist as an upper layer. Further, the control of the acidity of the resist underlying film enables control of the pattern form of the resist formed as an upper layer.

Examples of the photo-acid generator contained in the resist underlying film-forming composition for nanoimprinting of the present invention include onium salt compounds, sulfonimide compounds, and disulfonyldiazomethane compounds.

Examples of onium salt compounds include iodonium salt compounds, such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of sulfonimide compounds include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more.

When an acid generator is used, the amount of the acid generator is within the range of 0.01 to 10 parts by mass, or 0.1 to 8 parts by mass, or 0.5 to 5 parts by mass, relative to 100 parts by total solid content of the resist underlying film-forming composition for nanoimprinting.

The resist underlying film-forming composition for nanoimprinting of the present invention may contain optional components other than those mentioned above. The components are successively described below.

[Other Components]

In the resist underlying film-forming composition for nanoimprinting of the present invention, for further improving the application properties to prevent the occurrence of pinhole or striation and uneven surface, a surfactant may be incorporated into the composition. Examples of surfactants include nonionic surfactants, e.g., polyoxyethylene alkyl ethers, such as polyoxyethylene lauryl ether, polyoxyethylene stearyl ether, polyoxyethylene cetyl ether, and polyoxyethylene oleyl ether; polyoxyethylene alkyl aryl ethers, such as polyoxyethylene octylphenol ether and polyoxyethylene nonylphenol ether; polyoxyethylene-polyoxypropylene block copolymers; sorbitan fatty acid esters, such as sorbitan monolaurate, sorbitan monopalmitate, sorbitan monostearate, sorbitan monooleate, sorbitan trioleate, and sorbitan tristearate; and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine surfactants, such as EFTOP EF301, EF303, EF352 (trade name, manufactured by Tohchem Products Co., Ltd.), MEGAFACE F171, F173, R-40, R-40N, R-40LM (trade name, manufactured by DIC Corporation), Fluorad FC430, FC431 (trade name, manufactured by Sumitomo 3M), AsahiGuard AG710, Surflon S-382, SC101, SC102, SC103, SC104, SC105, SC106 (trade name, manufactured by AGC Inc.), and organosiloxane polymer KP341 (manufactured by Shin-Etsu Chemical Co., Ltd.). The amount of the surfactant incorporated is generally 2.0% by mass or less, preferably 1.0% by mass or less, based on the total solid content of the resist underlying film-forming composition. These surfactants may be used each alone or in combination of two or more. When a surfactant is used, the amount of the surfactant is within the range of 0.0001 to 5 parts by mass, or 0.001 to 1 part by mass, or 0.01 to 0.5 part by mass, relative to 100 parts by mass of the resist underlying film-forming composition for nanoimprinting.

In the resist underlying film-forming composition for nanoimprinting of the present invention, for example, a light absorber, a rheology modifier, or a bonding auxiliary may be added. The rheology modifier is effective in improving the fluidity of the resist underlying film-forming composition. The bonding auxiliary is effective in improving the adhesion between a semiconductor substrate or a resist and the resist underlying film.

As the light absorber, for example, a commercially available light absorber described in “Kougyo-you Shikiso no Gijutsu to Shijou (Techniques and Markets of Industrial Dyes)” (CMC Publishing Co., Ltd.) or “Senryo Binran (Dye Handbook)” (edited by The Society of Synthetic Organic Chemistry, Japan), for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163. C. I. Solvent Orange 2 and 45; C. I. Solvent Red 1, 3, 8, 23, 24, 25, 27, and 49; C. I. Pigment Green 10; and C. I. Pigment Brown 2 may be preferably used. The light absorber is generally incorporated in an amount of 10% by mass or less, preferably 5% by mass or less, based on the total solid content of the resist underlying film-forming composition for nanoimprinting.

A rheology modifier is added mainly for the purpose of improving the fluidity of the resist underlying film-forming composition for nanoimprinting, particularly for improving the uniformity of the thickness of the resist underlying film or the filling of the inside of hole with the resist underlying film-forming composition for nanoimprinting in the baking step. Specific examples of rheology modifiers include phthalic acid derivatives, such as dimethyl phthalate, diethyl phthalate, diisobutyl phthalate, dihexyl phthalate, and butylisodecyl phthalate; adipic acid derivatives, such as dinormalbutyl adipate, diisobutyl adipate, diisooctyl adipate, and octyldecyl adipate; maleic acid derivatives, such as dinormalbutyl maleate, diethyl maleate, and dinonyl maleate; oleic acid derivatives, such as methyl oleate, butyl oleate, and tetrahydrofurfuryl oleate; and stearic acid derivatives, such as normalbutyl stearate and glyceryl stearate. The rheology modifier is generally incorporated in an amount of less than 30% by mass, based on the total solid content of the resist underlying film-forming composition for nanoimprinting.

A bonding auxiliary is added mainly for the purpose of improving the adhesion between a substrate or a resist and the resist underlying film-forming composition for nanoimprinting to prevent the resist from peeling off particularly in the development. Specific examples of bonding auxiliaries include chlorosilanes, such as trimethylchlorosilane, dimethylmethylolchlorosilane, methyldiphenylchlorosilane, and chloromethyldimethylchlorosilane; alkoxysilanes, such as trimethylmethoxysilane, dimethyldiethoxysilane, methyldimethoxysilane, dimethylmethylolethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as methyloltrichlorosilane, γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. The bonding auxiliary is generally incorporated in an amount of less than 5% by mass, preferably less than 2% by mass, based on the total solid content of the resist underlying film-forming composition for nanoimprinting.

The resist underlying film-forming composition for nanoimprinting of the present invention generally has a solid content within the range of 0.1 to 70% by mass, preferably 0.1 to 60%/c by mass. The solid content indicates a content of the solids remaining after removing the solvent from the all components of the resist underlying film-forming composition for nanoimprinting. The proportion of the above-mentioned polymer in the solids is preferably within the range of 1 to 100% by mass, 1 to 99.9% by mass, 50 to 99.9% by mass, 50 to 95% by mass, and 50 to 90% by mass in increasing preference.

One measure for evaluating the uniform solution state of the resist underlying film-forming composition for nanoimprinting is to observe the state of the composition passing through a specific microfilter. The resist underlying film-forming composition for nanoimprinting of the present invention can pass through a microfilter having a pore diameter of 0.1 μm and is in a uniform solution state.

Examples of materials for the microfilter include fluororesins, such as PTFE (polytetrafluoroethylene) and PFA (tetrafluoroethylene-perfluoroalkyl vinyl ether copolymer), PE (polyethylene), UPE (ultra-high molecular weight polyethylene), PP (polypropylene), PSF (polysulfone), PES (polyether sulfone), and nylon, and a microfilter made of PTFE (polytetrafluoroethylene) is preferred.

A solvent and another optional component are incorporated into the novolac resin having a repeating unit structure represented by formula (1) in the present invention to obtain a resist underlying film-forming composition for nanoimprinting, and, when the composition is applied onto a substrate (silicon wafer), the applied composition gives a pure-water contact angle of 65° or more, when baked at 350° C.

A method for producing a resist underlying film, a method for forming a pattern, and a method for producing a semiconductor device, each using the resist underlying film-forming composition for nanoimprinting of the present invention, are described below.

[Method for Producing a Resist Underlying Film for Nanoimprinting]

The resist underlying film-forming composition for nanoimprinting of the present invention is applied onto a substrate used in the production of a semiconductor device (for example, a silicon wafer substrate, a silicon/silicon dioxide coated substrate, a silicon nitride substrate, a glass substrate, an ITO substrate, a polyimide substrate, or a low permittivity material (low-k material) coated substrate) by an appropriate application method, such as a spinner or a coater, and then baked to form a resist underlying film. The conditions for baking are appropriately selected from those at a baking temperature of 80 to 400° C. for a baking time of 0.3 to 60 minutes. Preferred conditions for baking are those at a baking temperature of 150 to 350° C. for a baking time of 0.5 to 2 minutes. The thickness of the formed resist underlying film is, for example, within the range of 10 to 1,000 nm, or 20 to 500 nm, or 30 to 400 nm, or 50 to 300 nm. Further, when a quartz substrate is used as a substrate, a replica of a quartz imprint mold (mold replica) can be formed.

Further, on the resist underlying film for nanoimprinting of the present invention, an adhesion layer and/or a silicone layer containing Si in an amount of 99% by mass or less or 50% by mass or less may be formed by application or vapor deposition. For example, the adhesion layer described in JP 2013-202982 A or Japanese Patent No. 5827180, or a layer of the silicon-containing resist underlying film (inorganic resist underlying film) forming composition described in WO 2009/104552 A1 may be formed by a spin coating method; or a Si inorganic material film may be formed by, for example, a CVD method.

Further, applying the resist underlying film-forming composition for nanoimprinting of the present invention onto a semiconductor substrate, which has a portion having a step and a portion having no step (so-called stepped substrate), followed by baking may provide a resist underlying film having a step in the range of from 3 to 70 nm for the portions of the substrate having a step and having no step.

[Method for Forming a Pattern]

The method for forming a pattern of the present invention comprises the steps of:

applying a curable composition onto the resist underlying film formed by the method for producing a resist underlying film of the present invention;

allowing the curable composition and a mold to be in contact;

irradiating the curable composition with a light or an electron beam to form a cured film; and

separating the cured film and the mold.

[Curable Composition]

With respect to the photoresist formed on the resist underlying film, there is no particular limitation as long as it is sensitive to a light used in the exposure. Any of a negative photoresist and a positive photoresist may be used. They include, for example, a positive photoresist comprising a novolac resin and 1,2-naphthoquinonediazidosulfonate; a chemical amplification photoresist comprising a binder having a group which is decomposed due to an acid to increase the alkali solubility, and a photo-acid generator; a chemical amplification photoresist comprising a low-molecular weight compound which is decomposed due to an acid to increase the alkali solubility of the photoresist, an alkali-soluble binder, and a photo-acid generator; and a chemical amplification photoresist comprising a binder having a group which is decomposed due to an acid to increase the alkali solubility, a low-molecular weight compound which is decomposed due to an acid to increase the alkali solubility of the photoresist, and a photo-acid generator. For example, they include trade name: APEX-E, manufactured by Shipley Company, Inc., trade name: PAR710, manufactured by Sumitomo Chemical Co., Ltd., and trade name: SEPR430, manufactured by Shin-Etsu Chemical Co., Ltd. Further, they also include fluorine atom-containing polymer photoresists described in, for example, Proc. SPIE, Vol. 3999, 330-334 (2000), Proc. SPIE, Vol. 3999, 357-364 (2000), and Proc. SPIE, Vol. 3999, 365-374 (2000).

[Step of Applying a Curable Composition]

This step is a step of applying a curable composition onto the resist underlying film formed by the method for producing a resist underlying film of the present invention. As a method of applying the curable composition, for example, an inkjet method, a dip coating method, an air knife coating method, a curtain coating method, a wire bar coating method, a gravure coating method, an extrusion coating method, a spin coating method, and a slit-scan method may be used. An inkjet method is suitable for applying droplets of the curable composition, and a spin coating method is suitable for coating the curable composition. This step may comprise forming an adhesion layer and/or a silicone layer containing Si in an amount of 99% by mass or less or 50% by mass or less by application or vapor deposition on the resist underlying film, and applying the curable composition onto the formed layer.

[Step of Allowing the Curable Composition and a Mold to be in Contact]

In this step, the curable composition and a mold are allowed to be in contact. For example, allowing the curable composition, which is a liquid, and a mold having a master pattern for transferring a pattern form to be in contact provides a liquid film of the curable composition filling the depressed portions of the fine pattern formed on the surface of the mold.

Taking into consideration the below-mentioned step of irradiating the curable composition with a light or an electron beam, it is recommended to use a mold using a light transmitting material as a base material. The base material for the mold is, specifically, preferably glass, quartz, a light transparent resin, such as PMMA or a polycarbonate resin, a transparent metal deposited film, a flexible film, such as polydimethylsiloxane, a photo-cured film, or a metal film. The base material for the mold is more preferably quartz, which has a small coefficient of thermal expansion and which is unlikely to cause pattern strain.

The fine pattern formed on the surface of the mold preferably has a pattern height of 4 to 200 nm. The pattern needs an appropriately large pattern height for improving the processing accuracy for the substrate; however, the smaller the pattern height, the smaller the force of peeling the mold off from the cured film in the below-mentioned step of separating the cured film and the mold, and the smaller the number of defects that the resist pattern breaks and remains on the mask side. It is recommended to select and employ a pattern height with an appropriate balance when taking the above into consideration.

Further, it is likely that elastic deformation of the resist pattern due to an impact of separating the mold causes the adjacent resist patterns to come into contact, so that the resist patterns suffer adhesion or breakage. This can be avoided when the pattern height is about 2 times or less the pattern width (the aspect ratio is 2 or less).

For improving the release property between the curable composition and the surface of the mold, the mold may preliminarily be subjected to surface treatment. Examples of the method for surface treatment include a method, in which a release agent is applied to the surface of the mold to form a release agent layer. Examples of release agents include a silicone release agent, a fluorine release agent, a hydrocarbon release agent, a polyethylene release agent, a polypropylene release agent, a paraffin release agent, a montan release agent, and a carnauba release agent. Preferred are a fluorine release agent and a hydrocarbon release agent. Examples of commercially available release agents include OPTOOL (registered trademark) DSX, manufactured by Daikin Industries, Ltd. The release agents may be used each alone or in combination of two or more.

In the present step, with respect to the pressure applied to the curable composition at the time of allowing the mold and the curable composition to be in contact, there is no particular limitation. A pressure within the range of 0 to 100 MPa is recommended. The pressure is preferably 0 MPa or more, and 50 MPa or less, 30 MPa or less, or 20 MPa or less.

When prespread of the droplets of the curable composition has proceeded in the previous step (the step of applying a curable composition), spread of the curable composition in the present step is quickly completed. Consequently, the time for allowing the mold and the curable composition to be in contact can be reduced. With respect to the time for allowing the mold and the curable composition to be in contact, there is no particular limitation, but the time is preferably 0.1 second or more and 600 seconds or less, 3 seconds or less, or 1 second or less. When the time for the contact is too short, there is concern that the “spread” and “fill” are unsatisfactory, so that a defect called an unfilling defect is caused.

The present step may be conducted in any of an air atmosphere, an atmosphere under a reduced pressure, and an inert gas atmosphere, but is preferably conducted under a pressure within the range of 0.0001 to 10 atm. For preventing an adverse effect of oxygen or moisture on the curing reaction, it is recommended that the present step should be conducted in an atmosphere under a reduced pressure or in an inert gas atmosphere. Specific examples of inert gas which may be used for creating an inert gas atmosphere include nitrogen, carbon dioxide, helium, argon, CFC, HCFC, HFC, and a mixed gas thereof.

The present step may be conducted in an atmosphere containing a condensable gas (hereinafter, referred to as “condensable gas atmosphere”). In the present specification, the term “condensable gas” means a gas such that when the gas fills, together with the curable composition, the depressed portions of the fine pattern formed in the mold as well as the gap between the mold and the substrate, the gas condenses due to a capillary pressure caused upon filling to be liquefied. The condensable gas is in a gaseous state in the atmosphere until the curable composition and the mold are made in contact in the present step. When the present step is conducted in a condensable gas atmosphere, the gas that fills the depressed portions of the fine pattern is liquefied due to a capillary pressure caused by the curable composition, which results in disappearance of air bubbles, achieving excellent filling property. The condensable gas may be dissolved in the curable composition.

With respect to the boiling point of the condensable gas, there is no particular limitation as long as it is not higher than the temperature of the atmosphere in the present step, but the boiling point of the condensable gas is preferably −10° C. or higher, or +10 or higher, and +23° C. or lower.

With respect to the vapor pressure of the condensable gas at the temperature of the atmosphere in the present step, there is no particular limitation as long as it is the mold pressure or less. The vapor pressure of the condensable gas is preferably in the range of from 0.1 to 0.4 MPa.

Specific examples of condensable gases include chlorofluorocarbon (CFC), such as trichlorofluoromethane; fluorocarbon (FC); hydrofluorocarbon (HFC), such as hydrochlorofluorocarbon (HCFC) and 1,1,1,3,3-pentafluoropropane (CHF₂CH₂CF₃, HFC-245 fa. PFP); and hydrofluoroether (HFE), such as pentafluoroethyl methyl ether (CF₃CF₂OCH₃, HFE-245 mc).

The condensable gases may be used each alone or in combination of two or more. The condensable gas may be used in the form of a mixture with a noncondensable gas, such as air, nitrogen, carbon dioxide, helium, or argon. As a noncondensable gas mixed with the condensable gas, air or helium is preferred.

[Step of Irradiating the Curable Composition with a Light or an Electron Beam to Form a Cured Film]

In the present step, the curable composition is irradiated with a light or electron beam to form a cured film. Specifically, the curable composition filling the fine pattern in the mold is irradiated with a light or electron beam through the mold to cure the curable composition filling the fine pattern in the mold as it is in such a state, forming a cured film having a pattern form.

The light or electron beam is selected according to the sensitivity wavelength of the curable composition. Specifically, the light or electron beam may be appropriately selected from, for example, an ultraviolet light, an X-ray, or an electron beam having a wavelength of 150 to 400 nm. Examples of the light sources for the light or electron beam include a high-pressure mercury lamp, an ultrahigh-pressure mercury lamp, a low-pressure mercury lamp, a Deep-UV lamp, a carbon-arc lamp, a chemical lamp, a metal halide lamp, a xenon lamp, a KrF excimer laser, an ArF excimer laser, and an F2 excimer laser. A single light source or two or more light sources may be used. Irradiation may be made with respect to the whole of the curable composition filling the fine pattern in the mold, or may be made with respect to only part of the region of the curable composition. The irradiation may be carried out to the entire region of the substrate with a light intermittently two or more times, or with a light continuously. Alternatively, the irradiation may be carried out in such a manner that the first irradiation is made with respect to a part of the region of the substrate, and the second irradiation is made with respect to a region different from the above part of the region.

The thus obtained cured film preferably has a pattern having a size of 1 nm or more, or 10 nm or more, and 10 mm or less, or 100 μm or less.

[Step of Separating the Cured Film and the Mold]

In the present step, the cured film and the mold are separated. The cured film having a pattern form is separated from the mold, so as to obtain a cured film having a pattern form in a self-supporting state, which corresponds to the reverse pattern of the fine pattern formed in the mold.

With respect to the method of separating the mold and the cured film having a pattern form, there is no particular limitation provided that the method moves the cured film and the mold in such a direction that the cured film and the mold are apart from each other, and that no part of the cured film having a pattern form physically breaks, and various conditions and others are not particularly limited, either. For example, the cured film and the mold may be separated by a method, in which the substrate is fixed and the mold is moved so that the mold is away from the substrate, or in which the mold is fixed and the substrate is moved so that the substrate is away from the mold. Alternatively, the cured film and the mold may be separated by a method, in which the substrate and the mold are moved by pulling them in the opposite directions.

In the case where the above-mentioned step of allowing the curable composition and a mold to be in contact is conducted in a condensable gas atmosphere, the pressure of the interface at which the cured film and the mold are in contact is reduced, when the cured film and the mold are separated in the present step, so that the condensable gas is vaporized. By virtue of this, it is possible to reduce the release force, which is a force needed for separating the cured film and the mold.

A cured film having in a desired position a desired uneven pattern form derived from the uneven form of the mold can be prepared through the above-described steps.

[Method for Producing a Semiconductor Device]

Using the pattern of the photoresist (upper layer) formed by the method for forming a pattern of the present invention as a protective film, the inorganic underlying film (intermediate layer) is removed, and then, using a film comprising the patterned photoresist and inorganic underlying film (intermediate layer) as a protective film, the organic underlying film (lower layer) is removed. Finally, using the patterned inorganic underlying film (intermediate layer) and organic underlying film (lower layer) as a protective film, processing of the semiconductor substrate is performed.

First, a portion of the inorganic underlying film (intermediate layer), from which the photoresist has been removed, is removed by dry etching so that the semiconductor substrate is exposed. In the dry etching for the inorganic underlying film, for example, a gas of tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane may be used. In the dry etching for the inorganic underlying film, a halogen-based gas is preferably used, and a fluorine-based gas is more preferably used. Examples of fluorine-based gases include tetrafluoromethane (CF₄), perfluorocyclobutane (C₄F₈), perfluoropropane (C₃F₈), trifluoromethane, and difluoromethane (CH₂F₂).

Then, using a film comprising the patterned photoresist and inorganic underlying film as a protective film, the organic underlying film is removed. The organic underlying film (lower layer) is preferably removed by dry etching using an oxygen-based gas. The reason for this is that the inorganic underlying film containing silicon atoms in a large amount is unlikely to be removed by dry etching using an oxygen-based gas.

Finally, processing of the semiconductor substrate is conducted. The processing of the semiconductor substrate is preferably conducted by dry etching using a fluorine-based gas.

Examples of fluorine-based gases include tetrafluoromethane (CF₄), perfluorocyclobutane (C₄F₈), perfluoropropane (C₃F₈), trifluoromethane, and difluoromethane (CH₂F₂).

Further, before forming the photoresist, an organic antireflection film may be formed on the resist underlying film as an upper layer. With respect to the antireflection film composition used in forming the antireflection film, there is no particular limitation, and an antireflection film composition may be arbitrarily selected from those which have been usually used in a lithography process, and an antireflection film may be formed by a method usually used, for example, by applying the composition using a spinner or coater followed by baking.

In the present invention, an organic underlying film is formed on a substrate, then an inorganic underlying film is formed on the organic film, and the resultant film may be covered with a photoresist. By virtue of this, even when a substrate is covered with a photoresist having a smaller thickness for preventing an occurrence of pattern collapse due to a reduced pattern width of the photoresist, appropriate selection of an etching gas enables processing of the substrate. For example, processing of the resist underlying film may be made by using as an etching gas a fluorine-based gas having an etching rate satisfactorily faster than that for the photoresist, and processing of the substrate may be made by using as an etching gas a fluorine-based gas having an etching rate satisfactorily faster than that for the inorganic underlying film, and further processing of the substrate may be made by using as an etching gas an oxygen-based gas having an etching rate satisfactorily faster than that for the organic underlying film.

The resist underlying film formed from the resist underlying film-forming composition may have an absorption with respect to the light used in a lithography process depending on the wavelength of the light. In such a case, the resist underlying film may function as an antireflection film having an effect of preventing a light reflected from the substrate. Further, the resist underlying film formed from the resist underlying film-forming composition of the present invention may function as a hard mask. The resist underlying film of the present invention may also be used as, for example, a layer for preventing an interaction between a substrate and a photoresist; a layer having a function for preventing any adverse effect on a substrate by the materials used in the photoresist or by the substances formed during the exposure to the photoresist; a layer having a function for preventing the diffusion of the substances generated from the substrate upon heating or baking into the upper layer photoresist; and a barrier layer for reducing the poisoning effect of the photoresist layer by the semiconductor substrate dielectric layer.

Moreover, the resist underlying film formed from the resist underlying film-forming composition is applied to a substrate having formed via holes used in a dual-damascene process, and may be used as an encapsulation material capable of completely filling holes. Furthermore, the resist underlying film may also be used as a planarization material for flattening the uneven surface of a semiconductor substrate.

### EXAMPLES

Hereinbelow, the present invention will be described in more detail with reference to the following Examples and others, which should not be construed as limiting the scope of the present invention.

The weight average molecular weight of the resin (polymer) obtained in Synthesis Example 1 below is the result of the measurement made by gel permeation chromatography (hereinafter, referred to simply as “GPC”). In the measurement, a GPC apparatus, manufactured by Tosoh Corp., was used and the conditions for the measurement and others are shown below.

GPC Column: Shodex KF803L, Shodex KF802, Shodex KF801 [registered trademark](Showa Denko K.K.)
Column temperature: 40° C.

### Solvent: Tetrahydrofuran (THF)

Flow rate: 1.0 ml/minute
Standard sample: Polystyrene (manufactured by Tosoh Corp.)

In the measurement of a dry etching rate, the below-shown etcher or etching gas was used.

RIE-10NR (manufactured by Samco Inc.): CF₄

### Synthesis Example 1

In a 100 mL two-necked flask were placed 9.71 g of 4-tert-butylbenzaldehyde (manufactured by Tokyo Chemical Industry Co., Ltd.), 10.00 g of carbazole (manufactured by Tokyo Chemical Industry Co., Ltd.), 48.68 g of propylene glycol monomethyl ether acetate (hereinafter, referred to as “PGMEA”), and 1.15 g of methanesulfonic acid (manufactured by Tokyo Chemical Industry Co., Ltd.). Then, the resultant mixture was heated to 150° C. and stirred under reflux for 30 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (2-1). The polymer had a weight average molecular weight Mw of 4,900, as determined by GPC using a conversion calibration curve obtained from the standard polystyrene.

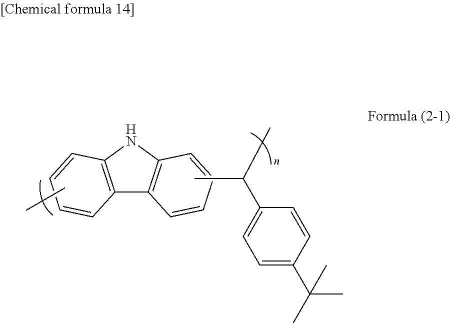

### Synthesis Example 2

In a 100 mL two-necked flask were placed 10.42 g of 4-(trifluoromethyl)-benzaldehyde (manufactured by Tokyo Chemical Industry Co., Ltd.), 10.00 g of carbazole (manufactured by Tokyo Chemical Industry Co., Ltd.), 50.34 g of PGMEA, and 1.15 g of methanesulfonic acid (manufactured by Tokyo Chemical Industry Co., Ltd.). Then, the resultant mixture was heated to 150° C. and stirred under reflux for 3.5 hours. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (2-2). The polymer had a weight average molecular weight Mw of 4,200, as determined by GPC using a conversion calibration curve obtained from the standard polystyrene.

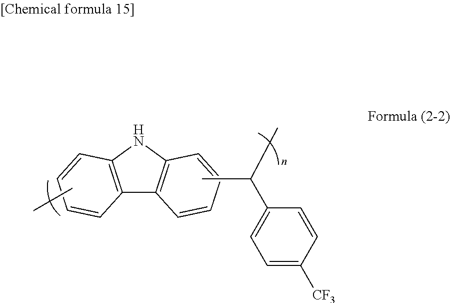

### Synthesis Example 3

In a 100 mL two-necked flask were placed 8.39 g of 4-tert-butylbenzaldehyde (manufactured by Tokyo Chemical Industry Co., Ltd.), 10.00 g of 2-phenylindole (manufactured by Tokyo Chemical Industry Co., Ltd.), 45.24 g of PGMEA, and 0.99 g of methanesulfonic acid (manufactured by Tokyo Chemical Industry Co., Ltd.). Then, the resultant mixture was heated to 150° C. and stirred under reflux for 17 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-3). The polymer had a weight average molecular weight Mw of 1,200, as determined by GPC using a conversion calibration curve obtained from the standard polystyrene.

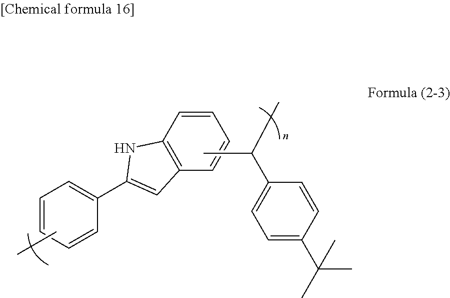

### Synthesis Example 4

In a 100 mL two-necked flask were placed 9.01 g of 4-(trifluoromethyl)-benzaldehyde (manufactured by Tokyo Chemical Industry Co., Ltd.), 10.00 g of 2-phenylindole (manufactured by Tokyo Chemical Industry Co., Ltd.), 46.68 g of PGMEA, and 0.99 g of methanesulfonic acid (manufactured by Tokyo Chemical Industry Co., Ltd.). Then, the resultant mixture was heated to 150° C. and stirred under reflux for 17 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-4). The polymer had a weight average molecular weight Mw of 2,200, as determined by GPC using a conversion calibration curve obtained from the standard polystyrene.

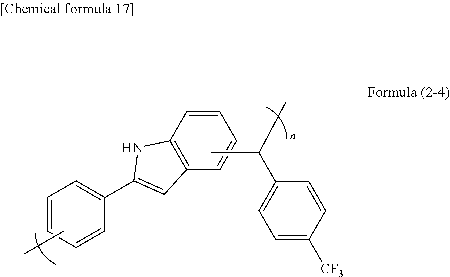

### Synthesis Example 5

In a 100 mL two-necked flask were placed 7.40 g of 4-tert-butylbenzaldehyde (manufactured by Tokyo Chemical Industry Co., Ltd.), 10.00 g of N-phenyl-1-naphthylamine (manufactured by Tokyo Chemical Industry Co., Ltd.), 18.50 g of PGMEA, and 1.10 g of methanesulfonic acid (manufactured by Tokyo Chemical Industry Co., Ltd.). Then, the resultant mixture was heated to 150° C. and stirred under reflux for 10 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (2-5). The polymer had a weight average molecular weight Mw of 6,000, as determined by GPC using a conversion calibration curve obtained from the standard polystyrene.

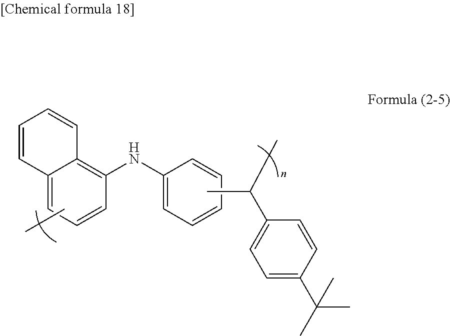

### Synthesis Example 6

In a 100 mL two-necked flask were placed 7.95 g of 4-(trifluoromethyl)-benzaldehyde (manufactured by Tokyo Chemical Industry Co., Ltd.), 10.00 g of N-phenyl-1-naphthylamine (manufactured by Tokyo Chemical Industry Co., Ltd.), 18.50 g of PGMEA, and 0.55 g of methanesulfonic acid (manufactured by Tokyo Chemical Industry Co., Ltd.). Then, the resultant mixture was heated to 150° C. and stirred under reflux for 10 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (2-6). The polymer had a weight average molecular weight Mw of 30,000, as determined by GPC using a conversion calibration curve obtained from the standard polystyrene.

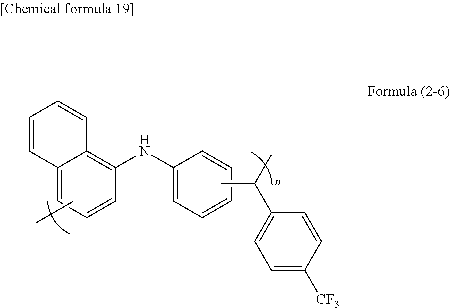

### Synthesis Example 7

In a 100 mL two-necked flask were placed 4.63 g of 4-tert-butylbenzaldehyde (manufactured by Tokyo Chemical Industry Co., Ltd.), 10.00 g of 9,9-bis(4-hydroxyphenyl)fluorene (manufactured by Tokyo Chemical Industry Co., Ltd.), 22.77 g of PGMEA, and 0.55 g of methanesulfonic acid (manufactured by Tokyo Chemical Industry Co., Ltd.). Then, the resultant mixture was heated to 150° C. and stirred under reflux for 5.5 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-7). The polymer had a weight average molecular weight Mw of 2,000, as determined by GPC using a conversion calibration curve obtained from the standard polystyrene.

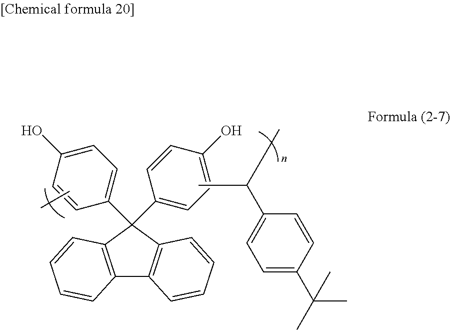

### Synthesis Example 8

In a 100 mL two-necked flask were placed 4.97 g of 4-(trifluoromethyl)-benzaldehyde (manufactured by Tokyo Chemical Industry Co., Ltd.), 10.00 g of 9,9-bis(4-hydroxyphenyl)fluorene (manufactured by Tokyo Chemical Industry Co., Ltd.), 23.28 g of PGMEA, and 0.55 g of methanesulfonic acid (manufactured by Tokyo Chemical Industry Co., Ltd.). Then, the resultant mixture was heated to 150° C. and stirred under reflux for 5.5 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-8). The polymer had a weight average molecular weight Mw of 10,000, as determined by GPC using a conversion calibration curve obtained from the standard polystyrene.

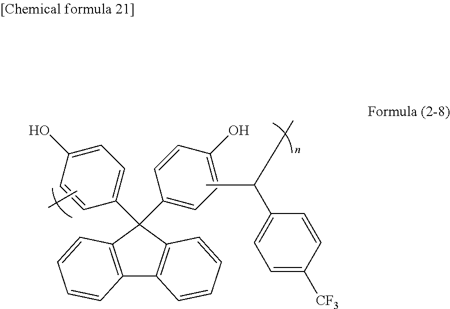

### Synthesis Example 9

In a 100 mL two-necked flask were placed 10.13 g of 4-tert-butylbenzaldehyde (manufactured by Tokyo Chemical Industry Co., Ltd.), 10.00 g of 1,5-dihydroxynaphthalene (manufactured by Tokyo Chemical Industry Co., Ltd.), 49.77 g of PGMEA, and 1.20 g of methanesulfonic acid (manufactured by Tokyo Chemical Industry Co., Ltd.). Then, the resultant mixture was heated to 150° C. and stirred under reflux for 1 hour and 45 minutes. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-9). The polymer had a weight average molecular weight Mw of 5,200, as determined by GPC using a conversion calibration curve obtained from the standard polystyrene.

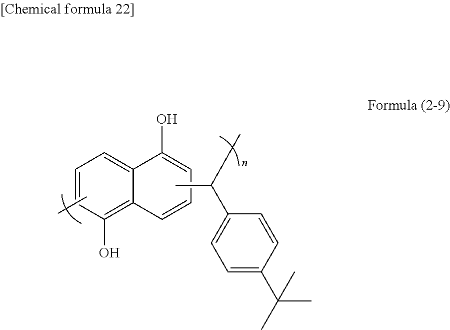

### Synthesis Example 10

In a 100 mL two-necked flask were placed 10.87 g of 4-(trifluoromethyl)-benzaldehyde (manufactured by Tokyo Chemical Industry Co., Ltd.), 10.00 g of 1,5-dihydroxynaphthalene (manufactured by Tokyo Chemical Industry Co., Ltd.), 51.50 g of PGMEA, and 1.20 g of methanesulfonic acid (manufactured by Tokyo Chemical Industry Co., Ltd.). Then, the resultant mixture was heated to 150° C. and stirred under reflux for 2 hours and 15 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (2-10). The polymer had a weight average molecular weight Mw of 8,300, as determined by GPC using a conversion calibration curve obtained from the standard polystyrene.

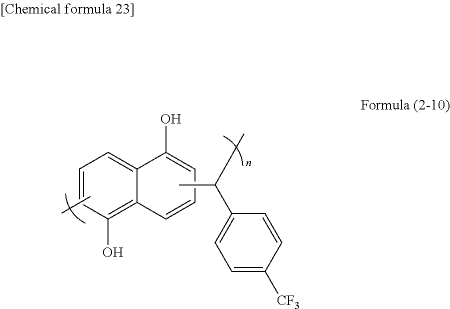

### Synthesis Example 11

In a 100 mL two-necked flask were placed 4.69 g of 4-tert-butylbenzaldehyde (manufactured by Tokyo Chemical Industry Co., Ltd.), 10.00 g of bisphenol M (manufactured by Tokyo Chemical Industry Co., Ltd.), 35.56 g of PGMEA, and 0.56 g of methanesulfonic acid (manufactured by Tokyo Chemical Industry Co., Ltd.). Then, the resultant mixture was heated to 150° C. and stirred under reflux for 16 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-11). The polymer had a weight average molecular weight Mw of 8,000, as determined by GPC using a conversion calibration curve obtained from the standard polystyrene.

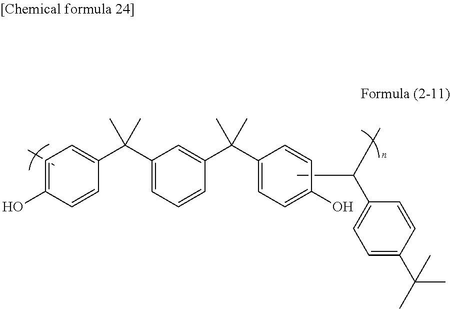

### Synthesis Example 12

In a 100 mL two-necked flask were placed 5.03 g of 4-(trifluoromethyl)-benzaldehyde (manufactured by Tokyo Chemical Industry Co., Ltd.), 10.00 g of bisphenol M (manufactured by Tokyo Chemical Industry Co., Ltd.), 36.36 g of PGMEA, and 0.56 g of methanesulfonic acid (manufactured by Tokyo Chemical Industry Co., Ltd.). Then, the resultant mixture was heated to 150° C. and stirred under reflux for 5 hours. After completion of the reaction, the resultant solution was dropwise added to a methanol/water mixture to cause reprecipitation. The resultant precipitate was subjected to filtration by means of suction, and the collected material was subjected to vacuum drying overnight at 60° C. The obtained polymer corresponded to formula (2-12). The polymer had a weight average molecular weight Mw of 6,500, as determined by GPC using a conversion calibration curve obtained from the standard polystyrene.

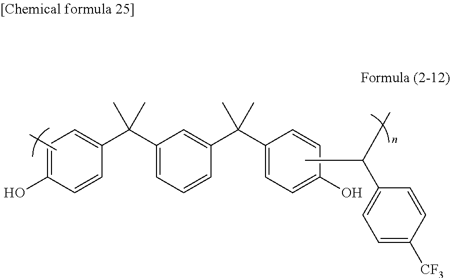

### Comparative Synthesis Example 1

In a 100 mL two-necked flask were placed 6.35 g of benzaldehyde (manufactured by Tokyo Chemical Industry Co., Ltd.), 10.00 g of carbazole (manufactured by Tokyo Chemical Industry Co., Ltd.), 40.84 g of PGMEA, and 1.15 g of methanesulfonic acid (manufactured by Tokyo Chemical Industry Co., Ltd.). Then, the resultant mixture was heated to 150° C. and stirred under reflux for about 30 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-1). The polymer had a weight average molecular weight Mw of 52,300, as determined by GPC using a conversion calibration curve obtained from the standard polystyrene.

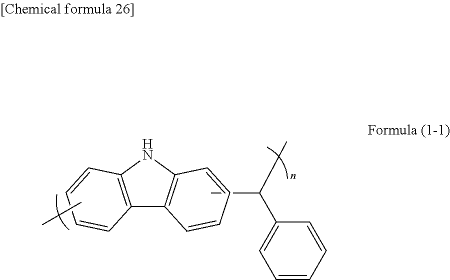

### Comparative Synthesis Example 2

In a 100 mL two-necked flask were placed 5.49 g of benzaldehyde (manufactured by Tokyo Chemical Industry Co., Ltd.), 10.00 g of 2-phenylindole (manufactured by Tokyo Chemical Industry Co., Ltd.), 16.49 g of PGMEA, and 0.99 g of methanesulfonic acid (manufactured by Tokyo Chemical Industry Co., Ltd.). Then, the resultant mixture was heated to 150° C. and stirred under reflux for about 5 hours. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-2). The polymer had a weight average molecular weight Mw of 1,600, as determined by GPC using a conversion calibration curve obtained from the standard polystyrene.

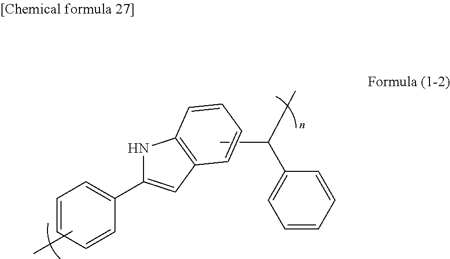

### Comparative Synthesis Example 3

In a 100 mL two-necked flask were placed 4.84 g of benzaldehyde (manufactured by Tokyo Chemical Industry Co., Ltd.), 10.00 g of N-phenyl-1-naphthylamine (manufactured by Tokyo Chemical Industry Co., Ltd.), 36.67 g of PGMEA, and 0.88 g of methanesulfonic acid (manufactured by Tokyo Chemical Industry Co., Ltd.). Then, the resultant mixture was heated to 150° C. and stirred under reflux for about 15 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-3). The polymer had a weight average molecular weight Mw of 5,900, as determined by GPC using a conversion calibration curve obtained from the standard polystyrene.

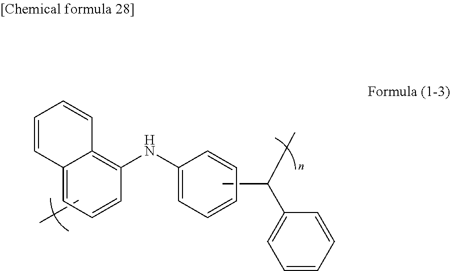

### Comparative Synthesis Example 4

In a 100 mL two-necked flask were placed 3.03 g of benzaldehyde (manufactured by Tokyo Chemical Industry Co., Ltd.), 10.00 g of 9,9-bis(4-hydroxyphenyl)fluorene (manufactured by Tokyo Chemical Industry Co., Ltd.), 32.68 g of PGMEA, and 0.55 g of methanesulfonic acid (manufactured by Tokyo Chemical Industry Co., Ltd.). Then, the resultant mixture was heated to 150° C. and stirred under reflux for about 17.5 hours. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-4). The polymer had a weight average molecular weight Mw of 10,300, as determined by GPC using a conversion calibration curve obtained from the standard polystyrene.

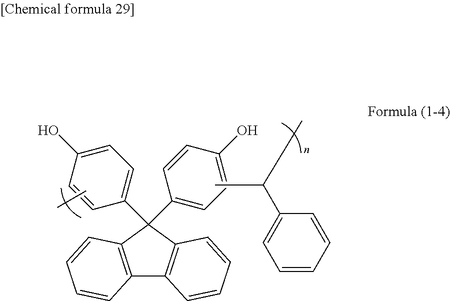

### Comparative Synthesis Example 5

In a 100 mL two-necked flask were placed 6.62 g of benzaldehyde (manufactured by Tokyo Chemical Industry Co., Ltd.), 10.00 g of 1,5-dihydroxynaphthalene (manufactured by Tokyo Chemical Industry Co., Ltd.), 41.58 g of PGMEA, and 1.20 g of methanesulfonic acid (manufactured by Tokyo Chemical Industry Co., Ltd.). Then, the resultant mixture was heated to 150° C. and stirred under reflux for about 1.5 hours. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-5). The polymer had a weight average molecular weight Mw of 5,300, as determined by GPC using a conversion calibration curve obtained from the standard polystyrene.

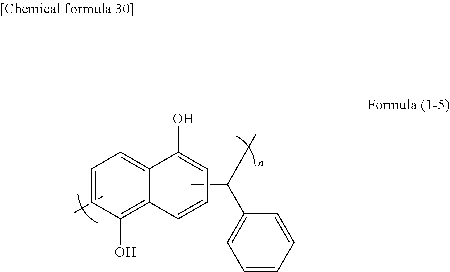

### Comparative Synthesis Example 6

In a 100 mL two-necked flask were placed 7.19 g of p-tolualdehyde (manufactured by Tokyo Chemical Industry Co., Ltd.), 10.00 g of carbazole (manufactured by Tokyo Chemical Industry Co., Ltd.), 42.80 g of PGMEA, and 1.15 g of methanesulfonic acid (manufactured by Tokyo Chemical Industry Co., Ltd.). Then, the resultant mixture was heated to 150° C. and stirred under reflux for about 30 minutes. After completion of the reaction, the resultant solution was dropwise added to methanol to cause reprecipitation. The resultant precipitate was subjected to filtration by means of suction, and the collected material was subjected to vacuum drying overnight at 60° C. The obtained polymer corresponded to formula (1-6). The polymer had a weight average molecular weight Mw of 5,900, as determined by GPC using a conversion calibration curve obtained from the standard polystyrene.

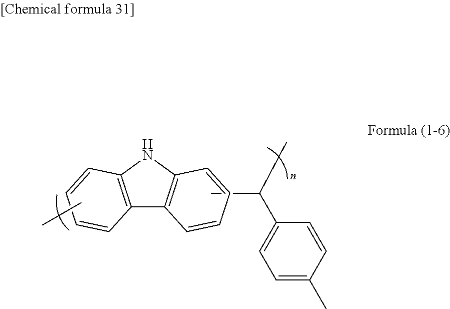

The chemical structures (examples) and abbreviations of the raw materials used in the Examples are as follows.

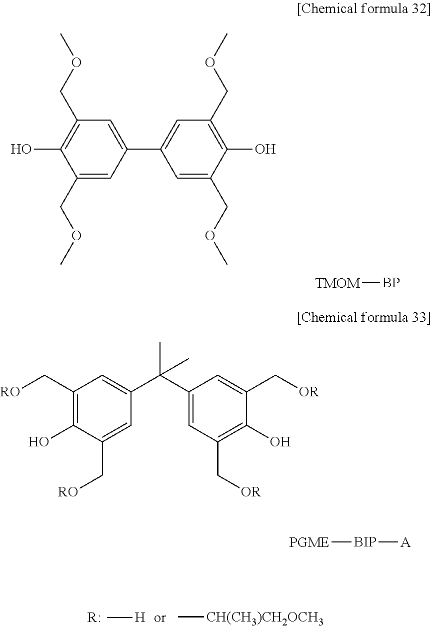

### Example 1

The resin obtained in Synthesis Example 1 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 2

The resin obtained in Synthesis Example 2 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 3

The resin obtained in Synthesis Example 3 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 4

The resin obtained in Synthesis Example 4 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 5

The resin obtained in Synthesis Example 5 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 6

The resin obtained in Synthesis Example 6 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 7

The resin obtained in Synthesis Example 7 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 8

The resin obtained in Synthesis Example 8 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 9

The resin obtained in Synthesis Example 9 was dissolved in propylene glycol monomethyl ether (hereinafter, referred to as “PGME”), and then subjected to ion exchange to obtain a resin solution (having a solid content of 22.6% by mass). PGME was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 10

The resin obtained in Synthesis Example 10 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 11

The resin obtained in Synthesis Example 11 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 12

The resin obtained in Synthesis Example 12 was dissolved in PGMEA, and then subjected to ion exchange to obtain a resin solution (having a solid content of 22.6% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Example 13

The resin obtained in Synthesis Example 1 was dissolved in PGMEA, and then subjected to ion exchange to obtain a resin solution (having a solid content of 22.6% by mass). In 2.65 g of the obtained resin solution were dissolved 0.12 g of 1% by mass surfactant (MEGAFACE R-40, manufactured by DIC Corporation) in PGMEA, 0.09 g of TMOM-BP (manufactured by Honshu Chemical Industry Co., Ltd.), 0.45 g of 2% by mass pyridinium p-hydroxybenzenesulfonate (Tokyo Chemical Industry Co., Ltd.) in PGME, 4.34 g of PGMEA, and 2.35 g of PGME. The resultant solution was subjected to filtration using a polytetrafluoroethylene microfilter having a pore diameter of 0.1 μm to prepare a resist underlying film-forming composition in the form of a solution.

### Example 14

The resin obtained in Synthesis Example 2 was dissolved in PGMEA, and then subjected to ion exchange to obtain a resin solution (having a solid content of 20.1% by mass). In 3.00 g of the obtained resin solution were dissolved 0.12 g of 1% by mass surfactant (MEGAFACE R-40, manufactured by DIC Corporation) in PGMEA, 0.09 g of TMOM-BP (manufactured by Honshu Chemical Industry Co., Ltd.), 0.34 g of 2% by mass pyridinium p-hydroxybenzenesulfonate (Tokyo Chemical Industry Co., Ltd.) in PGME, 4.00 g of PGMEA, and 2.49 g of PGME. The resultant solution was subjected to filtration using a polytetrafluoroethylene microfilter having a pore diameter of 0.1 μm to prepare a resist underlying film-forming composition in the form of a solution.

### Example 15

The resin obtained in Synthesis Example 3 was dissolved in PGMEA, and then subjected to ion exchange to obtain a resin solution (having a solid content of 19.0% by mass). In 1.94 g of the obtained resin solution were dissolved 0.07 g of 1% by mass surfactant (MEGAFACE R-40, manufactured by DIC Corporation) in PGMEA, 0.18 g of PGME-BIP-A (manufactured by Finechem Inc.), 0.46 g of 2% by mass pyridinium p-hydroxybenzenesulfonate (Tokyo Chemical Industry Co., Ltd.) in PGME, 2.91 g of PGMEA, and 1.43 g of PGME. The resultant solution was subjected to filtration using a polytetrafluoroethylene microfilter having a pore diameter of 0.1 μm to prepare a resist underlying film-forming composition in the form of a solution.

### Example 16

The resin obtained in Synthesis Example 4 was dissolved in PGMEA, and then subjected to ion exchange to obtain a resin solution (having a solid content of 20.8% by mass). In 2.02 g of the obtained resin solution were dissolved 0.08 g of 1% by mass surfactant (MEGAFACE R-40, manufactured by DIC Corporation) in PGMEA, 0.06 g of TMOM-BP (manufactured by Honshu Chemical Industry Co., Ltd.), 0.31 g of 2% by mass pyridinium p-hydroxybenzenesulfonate (Tokyo Chemical Industry Co., Ltd.) in PGME, 2.88 g of PGMEA, and 1.64 g of PGME. The resultant solution was subjected to filtration using a polytetrafluoroethylene microfilter having a pore diameter of 0.1 μm to prepare a resist underlying film-forming composition in the form of a solution.

### Example 17

The resin obtained in Synthesis Example 5 was dissolved in PGMEA, and then subjected to ion exchange to obtain a resin solution (having a solid content of 19.1% by mass). In 3.01 g of the obtained resin solution were dissolved 0.12 g of 1% by mass surfactant (MEGAFACE R-40, manufactured by DIC Corporation) in PGMEA, 0.19 g of PGME-BIP-A (manufactured by Finechem Inc.), 0.43 g of 2% by mass pyridinium p-hydroxybenzenesulfonate (Tokyo Chemical Industry Co., Ltd.) in PGME, 3.96 g of PGMEA, and 2.29 g of PGME. The resultant solution was subjected to filtration using a polytetrafluoroethylene microfilter having a pore diameter of 0.1 μm to prepare a resist underlying film-forming composition in the form of a solution.

### Example 18

The resin obtained in Synthesis Example 6 was dissolved in PGMEA, and then subjected to ion exchange to obtain a resin solution (having a solid content of 20.5% by mass). In 2.92 g of the obtained resin solution were dissolved 0.12 g of 1% by mass surfactant (MEGAFACE R-40, manufactured by DIC Corporation) in PGMEA, 0.09 g of TMOM-BP (manufactured by Honshu Chemical Industry Co., Ltd.), 0.45 g of 2% by mass pyridinium p-hydroxybenzenesulfonate (Tokyo Chemical Industry Co., Ltd.) in PGME, 4.07 g of PGMEA, and 2.35 g of PGME. The resultant solution was subjected to filtration using a polytetrafluoroethylene microfilter having a pore diameter of 0.1 μm to prepare a resist underlying film-forming composition in the form of a solution.

### Example 19

The resin obtained in Synthesis Example 7 was dissolved in PGMEA, and then subjected to ion exchange to obtain a resin solution (having a solid content of 22.2% by mass). In 2.56 g of the obtained resin solution were dissolved 0.11 g of 1% by mass surfactant (MEGAFACE R-40, manufactured by DIC Corporation) in PGMEA, 0.11 g of TMOM-BP (manufactured by Honshu Chemical Industry Co., Ltd.), 0.85 g of 2% by mass pyridinium p-hydroxybenzenesulfonate (Tokyo Chemical Industry Co., Ltd.) in PGME, 4.41 g of PGMEA, and 1.95 g of PGME. The resultant solution was subjected to filtration using a polytetrafluoroethylene microfilter having a pore diameter of 0.1 μm to prepare a resist underlying film-forming composition in the form of a solution.

### Example 20

The resin obtained in Synthesis Example 8 was dissolved in PGMEA, and then subjected to ion exchange to obtain a resin solution (having a solid content of 22.8% by mass). In 2.49 g of the obtained resin solution were dissolved 0.11 g of 1% by mass surfactant (MEGAFACE R-40, manufactured by DIC Corporation) in PGMEA, 0.11 g of TMOM-BP (manufactured by Honshu Chemical Industry Co., Ltd.), 0.85 g of 2% by mass pyridinium p-hydroxybenzenesulfonate (Tokyo Chemical Industry Co., Ltd.) in PGME, 4.47 g of PGMEA, and 1.95 g of PGME. The resultant solution was subjected to filtration using a polytetrafluoroethylene microfilter having a pore diameter of 0.1 μm to prepare a resist underlying film-forming composition in the form of a solution.

### Example 21

The resin obtained in Synthesis Example 9 was dissolved in PGME, and then subjected to ion exchange to obtain a resin solution (having a solid content of 19.7% by mass). In 2.88 g of the obtained resin solution were dissolved 0.11 g of 1% by mass surfactant (MEGAFACE R-40, manufactured by DIC Corporation) in PGMEA, 0.11 g of TMOM-BP (manufactured by Honshu Chemical Industry Co., Ltd.), 0.85 g of 2% by mass pyridinium p-hydroxybenzenesulfonate (Tokyo Chemical Industry Co., Ltd.) in PGME, 2.68 g of PGMEA, and 3.36 g of PGME. The resultant solution was subjected to filtration using a polytetrafluoroethylene microfilter having a pore diameter of 0.1 μm to prepare a resist underlying film-forming composition in the form of a solution.

### Example 22

The resin obtained in Synthesis Example 10 was dissolved in PGMEA, and then subjected to ion exchange to obtain a resin solution (having a solid content of 22.9% by mass). In 2.48 g of the obtained resin solution were dissolved 0.11 g of 1% by mass surfactant (MEGAFACE R-40, manufactured by DIC Corporation) in PGMEA, 0.11 g of TMOM-BP (manufactured by Honshu Chemical Industry Co., Ltd.), 0.85 g of 2% by mass pyridinium p-hydroxybenzenesulfonate (Tokyo Chemical Industry Co., Ltd.) in PGME, 4.48 g of PGMEA, and 1.95 g of PGME. The resultant solution was subjected to filtration using a polytetrafluoroethylene microfilter having a pore diameter of 0.1 μm to prepare a resist underlying film-forming composition in the form of a solution.

### Example 23

The resin obtained in Synthesis Example 11 was dissolved in PGMEA, and then subjected to ion exchange to obtain a resin solution (having a solid content of 17.9% by mass). In 1.93 g of the obtained resin solution were dissolved 0.07 g of 1% by mass surfactant (MEGAFACE R-40, manufactured by DIC Corporation) in PGMEA, 0.07 g of TMOM-BP (manufactured by Honshu Chemical Industry Co., Ltd.), 0.26 g of 2% by mass pyridinium p-hydroxybenzenesulfonate (Tokyo Chemical Industry Co., Ltd.) in PGME, 2.25 g of PGMEA, and 1.42 g of PGME. The resultant solution was subjected to filtration using a polytetrafluoroethylene microfilter having a pore diameter of 0.1 μm to prepare a resist underlying film-forming composition in the form of a solution.

### Example 24

The resin obtained in Synthesis Example 12 was dissolved in PGMEA, and then subjected to ion exchange to obtain a resin solution (having a solid content of 17.8% by mass). In 3.24 g of the obtained resin solution were dissolved 0.12 g of 1% by mass surfactant (MEGAFACE R-40, manufactured by DIC Corporation) in PGMEA, 0.12 g of TMOM-BP (manufactured by Honshu Chemical Industry Co., Ltd.), 0.43 g of 2% by mass pyridinium p-hydroxybenzenesulfonate (Tokyo Chemical Industry Co., Ltd.) in PGME, 3.73 g of PGMEA, and 2.37 g of PGME. The resultant solution was subjected to filtration using a polytetrafluoroethylene microfilter having a pore diameter of 0.1 μm to prepare a resist underlying film-forming composition in the form of a solution.

### Comparative Example 1

The resin obtained in Comparative Synthesis Example 1 was dissolved in PGMEA, and then subjected to ion exchange to obtain a resin solution (having a solid content of 18.4% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 2

The resin obtained in Comparative Synthesis Example 2 was dissolved in PGMEA, and then subjected to ion exchange to obtain a resin solution (having a solid content of 22.5% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 3

The resin obtained in Comparative Synthesis Example 3 was dissolved in cyclohexanone, and then subjected to ion exchange to obtain a resin solution (having a solid content of 17.7% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 4

The resin obtained in Comparative Synthesis Example 4 was dissolved in PGMEA, and then subjected to ion exchange to obtain a resin solution (having a solid content of 15.9% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 5

The resin obtained in Comparative Synthesis Example 5 was dissolved in PGME, and then subjected to ion exchange to obtain a resin solution (having a solid content of 18.2% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 6

The resin obtained in Comparative Synthesis Example 6 was dissolved in PGMEA, and then subjected to ion exchange to obtain a resin solution (having a solid content of 26.0% by mass). PGMEA was added to the resin solution so that the resin solution had a solid content of 5%. The resultant solution was subjected to filtration using a polytetrafluoroethylene microfilter having a pore diameter of 0.1 μm to prepare a resist underlying film-forming composition in the form of a solution.

### Comparative Example 7

The resin obtained in Comparative Synthesis Example 6 was dissolved in PGMEA, and then subjected to ion exchange to obtain a resin solution (having a solid content of 22.6% by mass). In 2.19 g of the obtained resin solution were dissolved 0.11 g of 1% by mass surfactant (MEGAFACE R-40, manufactured by DIC Corporation) in PGMEA, 0.11 g of TMOM-BP (manufactured by Honshu Chemical Industry Co., Ltd.), 0.85 g of 2% by mass pyridinium p-hydroxybenzenesulfonate (Tokyo Chemical Industry Co., Ltd.) in PGME, 4.78 g of PGMEA, and 1.95 g of PGME. The resultant solution was subjected to filtration using a polytetrafluoroethylene microfilter having a pore diameter of 0.1 μm to prepare a resist underlying film-forming composition in the form of a solution.

(Measurement of a Contact Angle of Polymers)

Each of the resist underlying film-forming compositions in the form of a solution prepared in Examples 1 to 12 and Comparative Examples 1 to 6 was applied onto a silicon wafer using a spin coater, and baked on a hotplate at 240° C. for 60 seconds or baked at 350° C. for 60 seconds to form a polymer film. Then, using a contact angle meter, manufactured by Kyowa Interface Science Co., Ltd., the pure-water contact angle of each of the polymer films was measured.

TABLE 1
Pure-water contact angle (°)

| | Baked at 240° C. | Baked at 350° C. |
|---|---|---|
| Example 1 | 86 | 73 |
| Example 2 | 82 | 74 |
| Example 3 | 88 | 81 |
| Example 4 | 86 | 83 |
| Example 5 | 85 | 81 |
| Example 6 | 84 | 84 |
| Example 7 | 79 | 73 |
| Example 8 | 79 | 77 |
| Example 9 | 77 | 71 |
| Example 10 | 76 | 73 |
| Example 11 | 86 | 80 |
| Example 12 | 86 | 82 |
| Comparative Example 1 | 70 | 54 |
| Comparative Example 2 | 73 | 68 |
| Comparative Example 3 | 72 | 69 |
| Comparative Example 4 | 69 | 66 |
| Comparative Example 5 | 57 | 53 |
| Comparative Example 6 | 75 | 47 |

As apparent from the above, the novolac resins having a tert-butyl group or a trifluoromethyl group exhibit a specifically high pure-water contact angle (=hydrophobic) not only when baked at a low temperature but also when baked at a high temperature and thus are clearly advantageous as compared to the resins having a closely related skeleton. In the next section, the results of evaluation of physical properties of the materials prepared by mixing any of the novolac resins having a tert-butyl group or a trifluoromethyl group with a crosslinking agent, an acid catalyst, and a surfactant, are shown.

(Measurement of a Contact Angle of Materials)

Each of the resist underlying film-forming compositions in the form of a solution prepared in Examples 13 to 24 and Comparative Example 7 was applied onto a silicon wafer using a spin coater, and baked on a hotplate at 350° C. for 60 seconds to form a 200 nm resist underlying film. Then, using a contact angle meter, manufactured by Kyowa Interface Science Co., Ltd., the pure-water contact angle was measured.

TABLE 2
Pure-water contact angle (°)

| | | Contact angle of |
|---|---|---|
| | | film baked at 350° C. |
| Example 13 | 350° C. Baked film | 75 |
| Example 14 | 350° C. Baked film | 73 |
| Example 15 | 350° C. Baked film | 78 |
| Example 16 | 350° C. Baked film | 80 |
| Example 17 | 350° C. Baked film | 77 |
| Example 18 | 350° C. Baked film | 79 |
| Example 19 | 350° C. Baked film | 66 |
| Example 20 | 350° C. Baked film | 69 |
| Example 21 | 350° C. Baked film | 67 |
| Example 22 | 350° C. Baked film | 68 |
| Example 23 | 350° C. Baked film | 74 |
| Example 24 | 350° C. Baked film | 76 |
| Comparative | 350° C. Baked film | 48 |
| Example 7 | | |

As apparent from the above, with respect to the novolac resins having a tert-butyl group or a trifluoromethyl group, the materials prepared from the novolac resin also exhibit a specifically high pure-water contact angle (=hydrophobic) when baked at high temperature. By virtue of this, the resultant films can be improved in their adhesion with a hydrophobic upper layer film, and further expected to have excellent permeability to hydrophobic gases.

(Test for Dissolution into Resist Solvents)

Each of the resist underlying film-forming compositions in the form of a solution prepared in Examples 13 to 24 and Comparative Example 7 was applied onto a silicon wafer using a spin coater, and baked on a hotplate at 350° C. for 60 seconds to form a resist underlying film (thickness: 0.20 μm). The formed resist underlying film was immersed in ethyl lactate, propylene glycol monomethyl ether, propylene glycol monomethyl ether acetate, and cyclohexanone, which are solvents used for a resist. The resist underlying films were insoluble in these solvents.

(Measurement of Optical Constants)

Each of the resist underlying film-forming compositions in the form of a solution prepared in Examples 13 to 24 and Comparative Example 7 was applied onto a silicon wafer using a spin coater. The applied composition was baked on a hotplate at 350° C. for 60 seconds to form a resist underlying film (thickness: 0.05 μm). With respect to the formed resist underlying film, using a spectroscopic ellipsometer, the refractive index (n value) and optical absorption coefficient (referred to also as “k value” or “attenuation coefficient”) at a wavelength of 193 nm were measured (Table 3).

TABLE 3
Refractive index n and optical absorption coefficient k

| | | n/k 193 nm |
|---|---|---|
| Example 13 | 350° C. Baked film | 1.48/0.54 |
| Example 14 | 350° C. Baked film | 1.51/0.52 |
| Example 15 | 350° C. Baked film | 1.53/0.62 |
| Example 16 | 350° C. Baked film | 1.58/0.64 |
| Example 17 | 350° C. Baked film | 1.44/0.52 |
| Example 18 | 350° C. Baked film | 1.46/0.54 |
| Example 19 | 350° C. Baked film | 1.43/0.58 |
| Example 20 | 350° C. Baked film | 1.44/0.58 |
| Example 21 | 350° C. Baked film | 1.47/0.46 |
| Example 22 | 350° C. Baked film | 1.48/0.46 |
| Example 23 | 350° C. Baked film | 1.51/0.59 |
| Example 24 | 350° C. Baked film | 1.53/0.60 |
| Comparative | 350° C. Baked film | 1.44/0.55 |
| Example 7 | | |

As apparent from the above, with respect to the novolac resins having a tert-butyl group or a trifluoromethyl group, the optical constants can be adjusted to be suitable for the process by changing their molecular skeleton.

[Measurement of a Dry Etching Rate]

Each of the resist underlying film-forming compositions in the form of a solution prepared in Examples 13 to 24 and Comparative Example 7 was applied onto a silicon wafer using a spin coater. The applied composition was baked on a hotplate at 350° C. for 60 seconds to form a resist underlying film (thickness: 0.20 μm). Using CF₄ gas as an etching gas, the dry etching rate was measured, and the dry etching rate ratio of Examples 13 to 24 and Comparative Example 7 was determined. The dry etching rate ratio is a ratio of (etching rate of resist underlying film)/(etching rate of KrF photoresist) (Table 4).

TABLE 4
Dry etching rate ratio

| | | Etching rate |
|---|---|---|
| Example 13 | 350° C. Baked film | 0.86 |
| Example 14 | 350° C. Baked film | 0.93 |
| Example 15 | 350° C. Baked film | 0.89 |
| Example 16 | 350° C. Baked film | 0.93 |
| Example 17 | 350° C. Baked film | 0.91 |
| Example 18 | 350° C. Baked film | 0.94 |
| Example 19 | 350° C. Baked film | 0.90 |
| Example 20 | 350° C. Baked film | 0.95 |
| Example 21 | 350° C. Baked film | 0.99 |
| Example 22 | 350° C. Baked film | 1.10 |
| Example 23 | 350° C. Baked film | 0.96 |
| Example 24 | 350° C. Baked film | 1.00 |
| Comparative | 350° C. Baked film | 0.90 |
| Example 7 | | |

As apparent from the above, with respect to the novolac resins having a tert-butyl group or a trifluoromethyl group, the etching rate can be adjusted to be suitable for the process by changing the molecular skeleton of the novolac resins.

(Test for Coverage for a Stepped Substrate)

As a test for coverage for a stepped substrate, using an SiO₂ substrate having a thickness of 200 nm, a comparison was made between the coating film thickness on the 800 nm trench area (TRENCH) and that on the open area (OPEN) having no pattern formed therein. Each of the resist underlying film-forming compositions prepared in Examples 13 to 24 and Comparative Example 7 was applied onto the above-mentioned substrate, and then baked at 350° C. for 60 seconds to form a resist underlying film having a thickness of about 200 nm. The planarization of the substrate was examined using a scanning electron microscope (S-4800), manufactured by Hitachi High-Technologies Corporation, and the planarization property was evaluated by measuring the difference in the thickness of the film between the trench area (pattern part) and the open area (non-pattern part) of the stepped substrate (wherein the difference in the thickness of the film corresponds to a coat step between the trench area and the open area, which is called bias). The planarization means that a difference in the thickness of the coating film applied onto the substrate (Iso-TRENCH bias) between the part in which a pattern is present (TRENCH (pattern part)) and the part in which no pattern is present (open area (non-pattern part)) is small (Table 5). Relative to the Comparative Example, the Example in which an improvement of less than 10 nm was confirmed was rated “Δ”, the Examples in which an improvement of 10 nm or more was confirmed were rated “∘”, and the Examples in which an improvement of 20 nm or more was confirmed were rated “⊚”.

TABLE 5
Evaluation of planarization

| | | Planarization |
|---|---|---|
| Example 13 | 350° C. Baked film | ⊚ |
| Example 14 | 350° C. Baked film | ◯ |
| Example 15 | 350° C. Baked film | ⊚ |
| Example 16 | 350° C. Baked film | ⊚ |
| Example 17 | 350° C. Baked film | ⊚ |
| Example 18 | 350° C. Baked film | ⊚ |
| Example 19 | 350° C. Baked film | ⊚ |
| Example 20 | 350° C. Baked film | ⊚ |
| Example 21 | 350° C. Baked film | Δ |
| Example 22 | 350° C. Baked film | ◯ |
| Example 23 | 350° C. Baked film | ⊚ |
| Example 24 | 350° C. Baked film | ⊚ |
| Comparative | 350° C. Baked film | X (Control) |
| Example 7 | | |

As apparent from the above, the novolac resins having a tert-butyl group or a trifluoromethyl group exhibit an excellent planarization property.

### INDUSTRIAL APPLICABILITY

The novolac resin according to the present invention exhibits a specifically high pure-water contact angle (=hydrophobic) not only when baked at low temperatures but also when baked at high temperatures. Moreover, the novolac resin according to the present invention, when made into a material by mixing the novolac resin with a crosslinking agent, an acid catalyst, and a surfactant, also exhibits a specifically high pure-water contact angle (=hydrophobic), when baked at high temperatures. Furthermore, the novolac resin according to the present invention exhibits an excellent planarization property and, by changing the molecular skeleton of the novolac resin, the optical constants and etching rate can be adjusted to be suitable for the process.

1. A resist underlying film-forming composition for nanoimprinting, comprising a novolac resin having a repeating unit structure represented by the following formula (1): 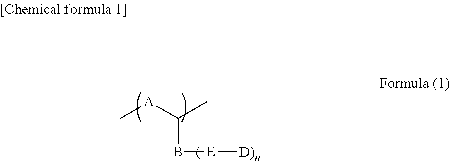
wherein:
group A represents an organic group having an aromatic ring, a fused aromatic ring, or a fused aromatic heterocycle;
group B represents an organic group having an aromatic ring or a fused aromatic ring;
group E represents a single bond, or a branched or linear alkylene group having 1 to 10 carbon atoms, which is optionally substituted and optionally contains an ether linkage and/or a carbonyl group;
group D represents an organic group having 1 to 15 carbon atoms, which is represented by the following formula (2): 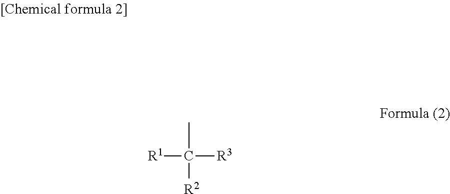
wherein each of R¹, R², and R³ is independently a fluorine atom or a linear, branched, or cyclic alkyl group, and any two of R¹, R², and R³ are optionally bonded to each other to form a ring; and
n represents a number of 1 to 5.

2. The resist underlying film-forming composition for nanoimprinting according to claim 1, wherein the group D is a tert-butyl group or a trifluoromethyl group.

3. The resist underlying film-forming composition for nanoimprinting according to claim 1, wherein the organic group having an aromatic ring, a fused aromatic ring, or a fused aromatic heterocycle for the group A is an organic group having one or more than one benzene rings, naphthalene rings, anthracene rings, or pyrene rings, or a fused ring between a benzene ring and a heterocycle or aliphatic ring.

4. The resist underlying film-forming composition for nanoimprinting according to claim 1, wherein the organic group having an aromatic ring, a fused aromatic ring, or a fused aromatic heterocycle for the group A is an organic group having 6 to 30 carbon atoms and optionally containing at least one heteroatom selected from N, S, and O on the ring, in the ring, or between the rings.

5. The resist underlying film-forming composition for nanoimprinting according to claim 1, wherein the group A is at least one member selected from the following groups: 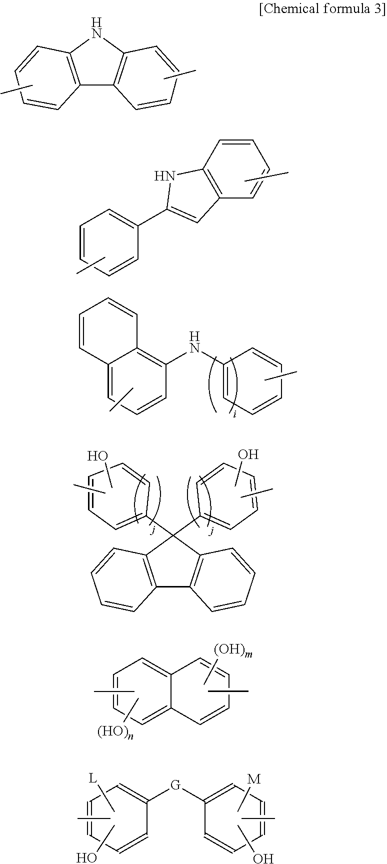
wherein each of i, j, m, and n is independently 1 or 2, G represents a direct bond or any one of the following formulae: 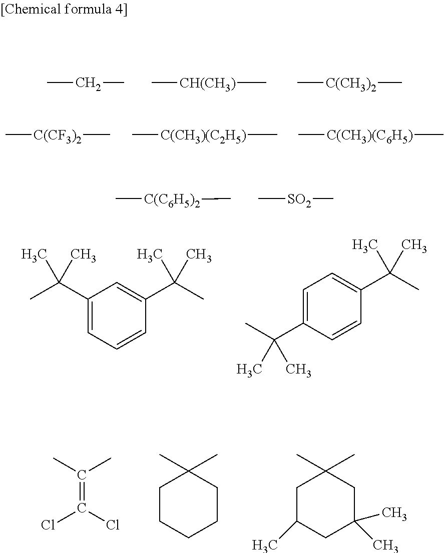
and
each of L and M independently represents a hydrogen atom, a phenyl group, or a C₁₋₃ alkyl group.

6. The resist underlying film-forming composition for nanoimprinting according to claim 1, wherein the group B is phenylene, biphenylene, naphthalenediyl, anthracenediyl, or phenanthrenediyl.

7. The resist underlying film-forming composition for nanoimprinting according to claim 1, wherein the group E is a single bond, or a linear alkylene group having 1 to 6 carbon atoms.

8. The resist underlying film-forming composition for nanoimprinting according to claim 1, wherein the group E is a single bond.

9. The resist underlying film-forming composition for nanoimprinting according to claim 1, which gives a pure-water contact angle of 76° or more when baked at 240° C., and gives a pure-water contact angle of 70° or more when baked at 350° C.

10. The resist underlying film-forming composition for nanoimprinting according to claim 1, further comprising a crosslinking agent.

11. The resist underlying film-forming composition for nanoimprinting according to claim 1, further comprising at least one member selected from the group consisting of an acid, a salt thereof, and an acid generator.

12. The resist underlying film-forming composition for nanoimprinting according to claim 10, which gives a pure-water contact angle of 65° or more when baked at 350° C.

13. A resist underlying film, which is a cured product of an applied film comprising the resist underlying film-forming composition for nanoimprinting according to claim 1.

14. A method for producing a resist underlying film, comprising applying the resist underlying film-forming composition for nanoimprinting according to claim 1 onto a semiconductor substrate and baking the applied composition.

15. A method for forming a pattern, comprising the steps of:
forming on a semiconductor substrate a resist underlying film from the resist underlying film-forming composition for nanoimprinting according to claim 1;
applying a curable composition onto the resist underlying film;
allowing the curable composition and a mold to be in contact;
irradiating the curable composition with a light or an electron beam to form a cured film; and
separating the cured film and the mold.

16. The method for forming a pattern according to claim 15, wherein the step of applying a curable composition onto the resist underlying film comprises forming an adhesion layer and/or a silicone layer containing Si in an amount of 99% by mass or less by application or vapor deposition on the resist underlying film, and applying the curable composition onto the formed layer.

17. A method for producing a semiconductor device, comprising the steps of:
forming on a semiconductor substrate a resist underlying film from the resist underlying film-forming composition for nanoimprinting according to claim 1;
forming a resist film on the resist underlying film;
irradiating the resist film with a light or an electron beam and subjecting the resultant resist film to development to form a resist pattern;
etching the resist underlying film through the formed resist pattern; and
processing the semiconductor substrate using the patterned resist underlying film.

18. A method for producing a semiconductor device, comprising the steps of:
forming on a semiconductor substrate a resist underlying film from the resist underlying film-forming composition for nanoimprinting according to claim 1;
forming a hard mask on the resist underlying film;
forming a resist film on the hard mask;
irradiating the resist film with a light or an electron beam and subjecting the resultant resist film to development to form a resist pattern;
etching the hard mask through the formed resist pattern;
etching the resist underlying film through the patterned hard mask; and
processing the semiconductor substrate using the patterned resist underlying film.
